(19) United States
(12) Patent Application Publication
(10) Pub. No.: US 2026/0093149 A1
(43) Pub. Date: Apr. 2, 2026

(54) ACTIVE MATRIX SUBSTRATE AND DISPLAY DEVICE

(71) Applicant: Sharp Display Technology Corporation, Kameyama City (JP)

(72) Inventors: Tetsuo KIKUCHI, Kameyama City (JP); Tohru Daitoh, Kameyama City (JP); Masahiko Suzuki, Kameyama City (JP); Setsuji Nishimiya, Kameyama City (JP); Hitoshi Takahata, Kameyama City (JP)

(21) Appl. No.: 19/341,084

(22) Filed: Sep. 26, 2025

(30) Foreign Application Priority Data
Sep. 30, 2024 (JP) 2024-170746

(51) Int. Cl. G02F 1/1362; G02F 1/1368; H10D 86/01; H10D 86/40; H10D 86/60; H10K 59/12; H10K 59/131

(52) U.S. Cl. CPC G02F 1/136204; G02F 1/136295; G02F 1/1368; H10D 86/0221; H10D 86/423; H10D 86/443; H10D 86/60; H10K 59/1201; H10K 59/1315

(57) ABSTRACT

An active matrix substrate includes a plurality of TFTs, and a plurality of ESD protection elements disposed in a non-display region, each of the plurality of ESD protection elements being electrically connected to a corresponding wiring line. At least some TFTs of the plurality of TFTs include a first oxide semiconductor layer. Each of the ESD protection elements includes a second oxide semiconductor layer that is formed in a layer separated from the first oxide semiconductor layer and has a mobility lower than a mobility of the first oxide semiconductor layer.

### CROSS-REFERENCE TO RELATED APPLICATIONS

This application claims the benefit of priority to Japanese Patent Application Number 2024-170746 filed on Sep. 30, 2024. The entire contents of the above-identified application are hereby incorporated by reference.

### BACKGROUND

### Technical Field

The disclosure relates to an active matrix substrate and, more particularly, to an active matrix substrate including an oxide semiconductor TFT. The disclosure also relates to a display device including such an active matrix substrate.

An active matrix substrate used in a liquid crystal display device, an organic electroluminescence (EL) display device, or the like includes a display region including a plurality of pixel regions, and a region other than the display region (a non-display region). In the display region, a thin film transistor (hereinafter referred to as a “TFT”) is provided as a switching element for each of the pixel regions. As such a TFT, in the related art, a TFT including an amorphous silicon layer serving as an active layer (hereinafter referred to as an “amorphous silicon TFT”) and a TFT including a polycrystalline silicon layer serving as an active layer (hereinafter referred to as a “polycrystalline silicon TFT”) have been widely used.

It has been proposed in recent years to use an oxide semiconductor as a material of the active layer of a TFT in place of amorphous silicon and polycrystalline silicon. A TFT including an oxide semiconductor layer serving as an active layer is hereinafter referred to as an “oxide semiconductor TFT”. The oxide semiconductor has a higher mobility than the amorphous silicon, and thus the oxide semiconductor TFT can operate at a higher speed than the amorphous silicon TFT.

A structure of the TFT is roughly classified into a bottom gate structure and a top gate structure. Currently, the bottom gate structure is adopted for the oxide semiconductor TFT in many cases, but it is also proposed to use the top gate structure (see, for example, JP 2015-109315 A). In the top gate structure, the gate insulating layer can be thinned, so that a high current drive capability can be obtained. In addition, a double gate structure in which gate electrodes are provided above and below an active layer has been recently proposed (for example, JP 6486174 B).

In the non-display region of the active matrix substrate, peripheral circuits including a TFT may be monolithically (integrally) formed. For example, by forming a drive circuit monolithically, cost reduction is achieved due to the non-display region being narrowed and the mounting process being simplified. For example, in the non-display region, a gate drive circuit is formed monolithically. In devices such as smartphones, where there is a high demand for frame narrowing, a demultiplexer circuit, which is also referred to as a source shared driving (SSD) circuit, may be formed monolithically.

In the present specification, a TFT disposed in each pixel of the display region (in the active matrix substrate used in an organic EL display device, a plurality of TFTs constituting a pixel circuit) is referred to as a “pixel TFT”. In addition, a TFT constituting a peripheral circuit provided in the non-display region is referred to as a “circuit TFT”.

The manufacturing process of an active matrix substrate includes a step in which static electricity readily occurs. Therefore, a protection element (referred to as an “ESD protection element” in the present specification) for protecting the pixel TFT, the circuit TFT, and the like from electrostatic discharge (ESD) may be provided on the active matrix substrate. JP 5284553 B discloses an active matrix substrate in which a diode-connected oxide semiconductor TFT is provided as an ESD protection element.

The ESD protection element of JP 5284553 B includes an oxide semiconductor layer formed in the same layer as an oxide semiconductor layer of a pixel TFT, and has a bottom gate structure. The oxide semiconductor layer of the ESD protection element includes offset regions that are located between the gate electrode and the source electrode and between the gate electrode and the drain electrode and that do not overlap any of the gate electrode, the source electrode, and the drain electrode in a plan view.

### SUMMARY

In the case in which the oxide semiconductor TFT is used as an ESD protection element, there are problems that, due to a high mobility of the oxide semiconductor layer, an excessive current flows through the ESD protection element during operation of the ESD protection element, resulting in damage to the ESD protection element, or voltages of various signals flowing through the wiring line are lowered due to a leakage current of the ESD protection element. In the active matrix substrate of JP 5284553 B, the oxide semiconductor layer of the ESD protection element has an offset region, and thus the above-described problems are suppressed.

However, in the case in which the oxide semiconductor TFT having the top gate structure is used as the ESD protection element, even when the offset region as disclosed in JP 5284553 B is provided in the oxide semiconductor layer, it is difficult to suppress the problems for the following reasons.

First, in the oxide semiconductor TFT having the top gate structure, a portion of the oxide semiconductor layer corresponding to the above-described offset region is a region having a reduced resistance (made conductive), and has a small effect of suppressing a current. In addition, since a gate insulating layer thinner than that of the bottom gate structure is generally used in the top gate structure, the oxide semiconductor TFT of the top gate structure has a higher current drive capability than the oxide semiconductor TFT of the bottom gate structure.

For these reasons, in the case in which the oxide semiconductor TFT having the top gate structure is used as the ESD protection element, it is difficult to suppress the defects caused by the high mobility of the oxide semiconductor layer. Furthermore, oxide semiconductors having the higher mobility have been developed in recent years, and when such an oxide semiconductor is used, the current drive capability of the ESD protection element is further increased, and it becomes more difficult to suppress the above-described problems.

Also in the case in which the oxide semiconductor TFT having the double gate structure is used as the ESD protection element, it is difficult to suppress the defects caused by the high mobility of the oxide semiconductor layer for the same reason as in the case of the top gate structure.

An embodiment of the disclosure has been conceived in light of the above-described problems, and an object of the disclosure is to avoid, in the active matrix substrate including the oxide semiconductor TFT having the top gate structure or the double gate structure as an ESD protection element, the defects caused by an excessively high current drive capability of the ESD protection element.

The present specification discloses an active matrix substrate and a display device described in the following Items.

### Item 1

An active matrix substrate that includes a display region including a plurality of pixel regions, and a non-display region located around the display region, the active matrix substrate including:
a substrate;
a plurality of wiring lines provided on the substrate, the plurality of wiring lines including a plurality of gate wiring lines and a plurality of source wiring lines;
a plurality of TFTs supported by the substrate, the plurality of TFTs including a plurality of pixel TFTs disposed in the display region and a plurality of circuit TFTs disposed in the non-display region; and
a plurality of ESD protection elements disposed in the non-display region, each of the plurality of ESD protection elements being electrically connected to a corresponding wiring line of the plurality of wiring lines,
in which at least some TFTs of the plurality of TFTs include:
a first oxide semiconductor layer including a first channel region, and a first source contact region and a first drain contact region located on both sides of the first channel region;
a first gate insulating layer provided at least on the first channel region;
a first gate electrode facing the first channel region via the first gate insulating layer; and
a first source electrode and a first drain electrode electrically connected to the first source contact region and the first drain contact region, respectively, and
each of the plurality of ESD protection elements includes:
a second oxide semiconductor layer including a second channel region, and a second source contact region and a second drain contact region located on both sides of the second channel region, the second oxide semiconductor layer being formed in a layer separated from the first oxide semiconductor layer and having a mobility lower than a mobility of the first oxide semiconductor layer;
a second gate insulating layer provided at least on the second channel region;
a second gate electrode facing the second channel region via the second gate insulating layer; and
a second source electrode and a second drain electrode electrically connected to the second source contact region and the second drain contact region, respectively.

### Item 2

The active matrix substrate according to item 1, in which the second gate insulating layer includes a first layer and a second layer provided on the first layer, the second layer being formed in the same layer as the first gate insulating layer.

### Item 3

The active matrix substrate according to item 2, further including an interlayer insulating layer covering the second oxide semiconductor layer, the second gate insulating layer, and the second gate electrode,
in which a source contact hole exposing part of the second source contact region and a drain contact hole exposing part of the second drain contact region are formed at least in the interlayer insulating layer, and
the first layer of the second gate insulating layer covers a portion of the second source contact region not overlapping the source contact hole, and a portion of the second drain contact region not overlapping the drain contact hole.

### Item 4

The active matrix substrate according to item 3, in which the second layer of the second gate insulating layer covers a portion of the second source contact region not overlapping the source contact hole and a portion of the second drain contact region not overlapping the drain contact hole.

### Item 5

The active matrix substrate according to any one of items 1 to 4, in which in a plan view, a protrusion width of the second gate insulating layer from the second gate electrode toward the second source contact region side is larger than a protrusion width of the first gate insulating layer from the first gate electrode toward the first source contact region side, and a protrusion width of the second gate insulating layer from the second gate electrode toward the second drain contact region side is larger than a protrusion width of the first gate insulating layer from the first gate electrode toward the first drain contact region side.

### Item 6

The active matrix substrate according to any one of items 1 to 5,
in which the at least some TFTs further include:
a third gate electrode located below the first oxide semiconductor layer and facing the at least first channel region, and
a third gate insulating layer located between the first oxide semiconductor layer and the third gate electrode.

### Item 7

The active matrix substrate according to item 6, in which the third gate electrode protrudes from the first gate electrode toward the first source contact region side and toward the first drain contact region side in a plan view.

### Item 8

The active matrix substrate according to any one of items 1 to 7,
in which each of the plurality of ESD protection elements further includes:
a fourth gate electrode located below the second oxide semiconductor layer and facing the at least second channel region, and
a fourth gate insulating layer located between the second oxide semiconductor layer and the fourth gate electrode.

### Item 9

The active matrix substrate according to item 8, in which the fourth gate electrode protrudes from the second gate electrode toward the second source contact region side and toward the second drain contact region side in a plan view.

### Item 10

The active matrix substrate according to any one of items 1 to 9,
in which the second gate electrode and the second source electrode are electrically connected to each other.

### Item 11

The active matrix substrate according to any one of items 1 to 10,
in which the second gate electrode is formed in the same layer as the first gate electrode, and
the second source electrode and the second drain electrode are formed in the same layer as a layer in which the first source electrode is formed.

### Item 12

The active matrix substrate according to any one of items 1 to 11, in which at least part of the plurality of pixel TFTs includes a third oxide semiconductor layer formed in the same layer as the second oxide semiconductor layer.

### Item 13

The active matrix substrate according to item 12, in which each of the plurality of pixel TFTs includes the third oxide semiconductor layer.

### Item 14

The active matrix substrate according to item 12,
in which part of the plurality of pixel TFTs includes the third oxide semiconductor layer, and
another part of the plurality of pixel TFTs includes the first oxide semiconductor layer.

### Item 15

The active matrix substrate according to any one of items 1 to 14, in which at least part of the plurality of circuit TFTs includes the first oxide semiconductor layer.

### Item 16

The active matrix substrate according to any one of items 1 to 15,
in which the first oxide semiconductor layer and the second oxide semiconductor layer each contain In and/or Sn, and
a sum of atomic ratios of In and Sn to all metal elements in the second oxide semiconductor layer is smaller than a sum of atomic ratios of In and Sn to all metal elements in the first oxide semiconductor layer.

### Item 17

The active matrix substrate according to any one of items 1 to 15, in which both the first oxide semiconductor layer and the second oxide semiconductor layer contain an In—Ga—Zn—O based semiconductor, and an atomic ratio of In to all metal elements in the second oxide semiconductor layer is smaller than an atomic ratio of In to all metal elements in the first oxide semiconductor layer.

### Item 18

A display device including the active matrix substrate according to any one of items 1 to 17.

### Item 19

The display device according to item 18, in which the display device is a liquid crystal display device.

### Item 20

The display device according to item 18, in which the display device is an organic EL display device.

According to the embodiments of the disclosure, in an active matrix substrate including an oxide semiconductor TFT having a top gate structure or a double gate structure as an ESD protection element, it is possible to avoid a problem caused by an excessively high current drive capability of the ESD protection element.

### BRIEF DESCRIPTION OF DRAWINGS

The disclosure will be described with reference to the accompanying drawings, wherein like numbers reference like elements.

FIG. 1 is a schematic view illustrating an example of a planar structure of an active matrix substrate 100 according to an embodiment of the disclosure in a case in which the active matrix substrate 100 is for a liquid crystal display device.

FIG. 2 is an equivalent circuit diagram of a pixel region P.

FIG. 3 is a schematic view illustrating an example of a planar structure of the active matrix substrate 100 in a case in which the active matrix substrate 100 is for an organic EL display device.

FIG. 4 is an equivalent circuit diagram of the pixel region P.

FIG. 5 is a cross-sectional view schematically illustrating part of the active matrix substrate 100.

FIG. 6 is a plan view schematically illustrating part of the active matrix substrate 100.

FIG. 7A is a process cross-sectional view for explaining a method of manufacturing the active matrix substrate 100.

FIG. 7B is a process cross-sectional view for explaining the method of manufacturing the active matrix substrate 100.

FIG. 7C is a process cross-sectional view for explaining the method of manufacturing the active matrix substrate 100.

FIG. 7D is a process cross-sectional view for explaining the method of manufacturing the active matrix substrate 100.

FIG. 7E is a process cross-sectional view for explaining the method of manufacturing the active matrix substrate 100.

FIG. 7F is a process cross-sectional view for explaining the method of manufacturing the active matrix substrate 100.

FIG. 7G is a process cross-sectional view for explaining the method of manufacturing the active matrix substrate 100.

FIG. 7H is a process cross-sectional view for explaining the method of manufacturing the active matrix substrate 100.

FIG. 7I is a process cross-sectional view for explaining the method of manufacturing the active matrix substrate 100.

FIG. 7J is a process cross-sectional view for explaining the method of manufacturing the active matrix substrate 100.

FIG. 8 is a cross-sectional view schematically illustrating part of an active matrix substrate 200A according to an embodiment of the disclosure.

FIG. 9 is a cross-sectional view schematically illustrating part of an active matrix substrate 200B according to an embodiment of the disclosure.

FIG. 10 is a cross-sectional view schematically illustrating part of an active matrix substrate 300 according to an embodiment of the disclosure.

FIG. 11 is a cross-sectional view schematically illustrating part of an active matrix substrate 400A according to an embodiment of the disclosure.

FIG. 12 is a cross-sectional view schematically illustrating part of an active matrix substrate 400B according to an embodiment of the disclosure.

FIG. 13 is a cross-sectional view schematically illustrating part of an active matrix substrate 400C according to an embodiment of the disclosure.

FIG. 14A is a process cross-sectional view for explaining a method of manufacturing the active matrix substrate 400A.

FIG. 14B is a process cross-sectional view for explaining the method of manufacturing the active matrix substrate 400A.

FIG. 14C is a process cross-sectional view for explaining the method of manufacturing the active matrix substrate 400A.

FIG. 14D is a process cross-sectional view for explaining the method of manufacturing the active matrix substrate 400A.

FIG. 14E is a process cross-sectional view for explaining the method of manufacturing the active matrix substrate 400A.

FIG. 15 is a cross-sectional view schematically illustrating part of an active matrix substrate 500A according to an embodiment of the disclosure.

FIG. 16 is a cross-sectional view schematically illustrating part of an active matrix substrate 500B according to an embodiment of the disclosure.

FIG. 17 is a cross-sectional view schematically illustrating part of an active matrix substrate 500C according to an embodiment of the disclosure.

FIG. 18A is a process cross-sectional view for explaining a method of manufacturing the active matrix substrate 500A.

FIG. 18B is a process cross-sectional view for explaining the method of manufacturing the active matrix substrate 500A.

FIG. 18C is a process cross-sectional view for explaining the method of manufacturing the active matrix substrate 500A.

FIG. 18D is a process cross-sectional view for explaining the method of manufacturing the active matrix substrate 500A.

FIG. 18E is a process cross-sectional view for explaining the method of manufacturing the active matrix substrate 500A.

FIG. 19 is a process cross-sectional view illustrating steps of patterning an upper gate conductive film CF and insulating films IF2 and IF1 when manufacturing the active matrix substrate 100.

FIG. 20 is a process cross-sectional view illustrating steps of patterning the upper gate conductive film CF and the insulating film IF2 when manufacturing the active matrix substrate 400A.

FIG. 21 is a process cross-sectional view illustrating steps of patterning the upper gate conductive film CF when manufacturing the active matrix substrate 500A.

### DESCRIPTION OF EMBODIMENTS

Hereinafter, embodiments of the disclosure will be described with reference to the accompanying drawings. Note that the disclosure is not limited to the embodiments described below.

### First Embodiment

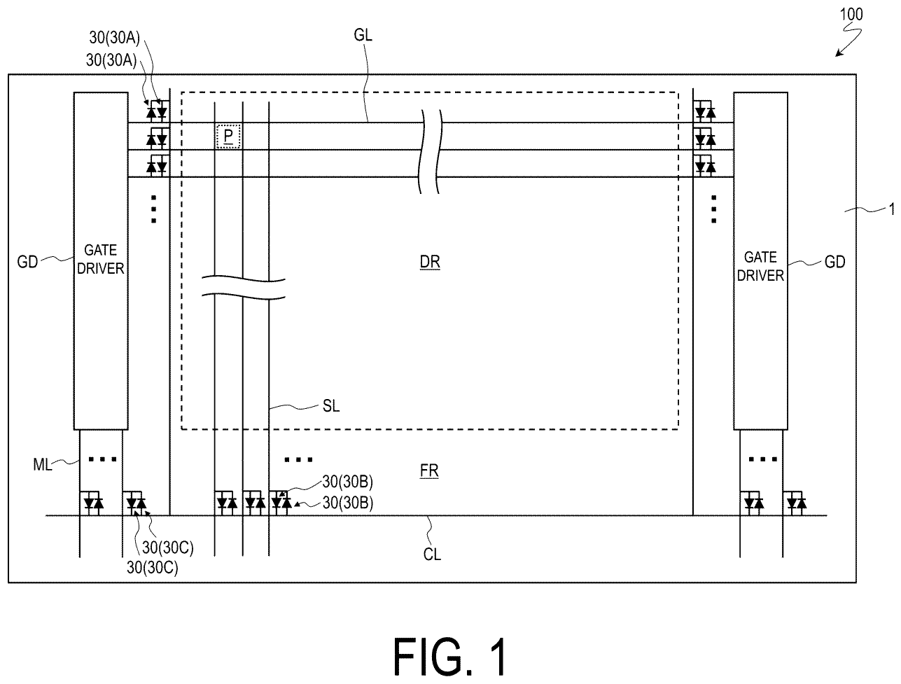

An overview of a structure of an active matrix substrate 100 according to the present embodiment will be described with reference to FIG. 1. FIG. 1 is a schematic view illustrating an example of a planar structure of the active matrix substrate 100 in a case in which the active matrix substrate 100 is for a liquid crystal display device. The active matrix substrate 100 includes a display region DR and a non-display region FR as illustrated in FIG. 1.

The display region DR includes a plurality of pixel regions P arranged in a matrix shape. The pixel region P is a region corresponding to a pixel of the display device.

The non-display region FR is located around the display region DR. The non-display region FR is referred to as a “peripheral region” or “frame region” in some cases.

The constituent element of the active matrix substrate 100 is supported by a substrate 1. The substrate 1 is, for example, a glass substrate.

A plurality of wiring lines including a plurality of gate wiring lines GL and a plurality of source wiring lines SL are provided on the substrate 1. The plurality of gate wiring lines GL each extend in a row direction. The plurality of source wiring lines SL each extend in a column direction.

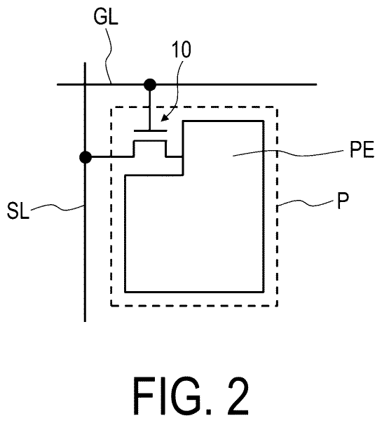

Typically, a region surrounded by two gate wiring lines GL adjacent to each other and two source wiring lines SL adjacent to each other is the pixel region P. FIG. 2 illustrates an example of an equivalent circuit of the pixel region P. Each pixel region P includes a pixel TFT 10 and a pixel electrode PE as illustrated in FIG. 2.

Each pixel TFT 10 is supported by the substrate 1 and includes a gate electrode, a source electrode, a drain electrode, and an oxide semiconductor layer.

The gate electrode and the source electrode of the pixel TFT 10 are electrically connected to the corresponding gate wiring line GL and the corresponding source wiring line SL, respectively. The drain electrode of the pixel TFT 10 is electrically connected to the pixel electrode PE.

A gate driver (gate wiring line drive circuit) GD that drives the gate wiring line GL, and a source driver (source wiring line drive circuit: not illustrated) that drives the source wiring line SL are disposed in the non-display region FR. In the present embodiment, the gate driver GD is a GDM circuit integrally (monolithically) formed on the substrate 1. In the example illustrated in the figure, the gate driver GD is disposed on each of the left side and the right side of the non-display region FR, but the gate driver GD may be disposed only on one side. Each of the gate wiring lines GL is connected to a respective one of a plurality of output terminals of the gate driver GD. In this example, the source driver is mounted on the substrate 1 (for example, COG mounting). Each of the source wiring lines SL is connected to a respective one of a plurality of output terminals of the source driver.

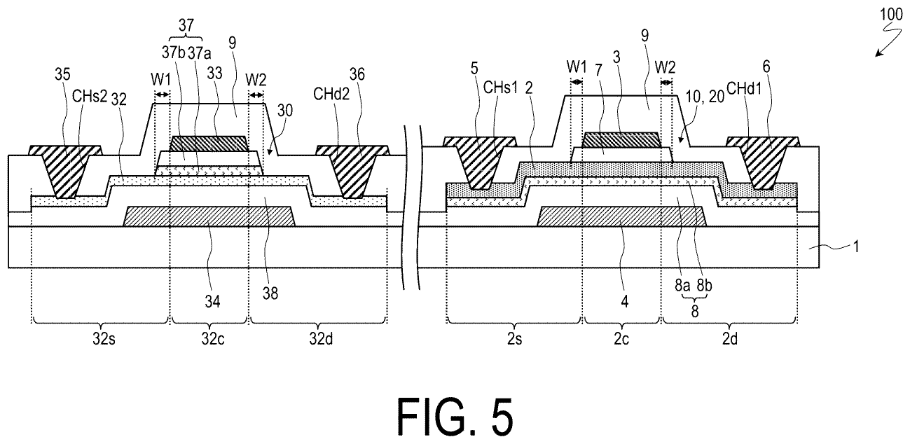

Although not illustrated in FIG. 1, a plurality of circuit TFTs 20 (see FIG. 5 and the like described below) are disposed in the non-display region FR. The plurality of circuit TFTs 20 are supported by the substrate 1. As illustrated, when the GDM circuit is formed in the non-display region FR, the plurality of circuit TFTs 20 include the circuit TFT 20 constituting the GDM circuit.

In the non-display region FR, a plurality of wiring lines (hereinafter, referred to as “GDM wiring lines”) ML for supplying signals to the gate driver (GDM circuit) GD are provided on the substrate 1. The plurality of GDM wiring lines ML include, for example, a plurality of clock signal lines for supplying a clock signal (CK), a low-potential wiring line for supplying a power supply voltage (VSS) on the low-potential side of a gate signal, a start pulse wiring line for giving a start signal (GSP) to a start stage of a shift register, a reset wiring line for resetting a specific node in the gate driver (GDM circuit) GD to a constant potential, and the like. In the example illustrated in the figure, a common wiring line CL for supplying a common voltage is also provided in the non-display region FR so as to surround the display region DR.

The active matrix substrate 100 further includes a plurality of ESD protection elements 30 disposed in the non-display region FR. Each of the plurality of ESD protection elements 30 is electrically connected to a corresponding wiring line. As described below, each of the ESD protection elements 30 is a diode-connected oxide semiconductor TFT and can function as a diode element. Here, the plurality of ESD protection elements 30 include ESD protection elements 30A electrically connected to the respective gate wiring lines GL and the common wiring line CL, ESD protection elements 30B electrically connected to the respective source wiring lines SL and the common wiring line CL, and ESD protection elements 30C electrically connected to the respective GDM wiring lines ML and the common wiring line CL.

In the example illustrated in the figure, two ESD protection elements 30A are provided on each of the left side and the right side of the non-display region FR for each of the gate wiring lines GL. The two ESD protection elements 30A are connected in parallel between the gate wiring line GL and the common wiring line CL so that the forward directions thereof are opposite to each other. Two ESD protection elements 30B are provided for each of the source wiring lines SL. The two ESD protection elements 30B are connected in parallel between the source wiring line SL and the common wiring line CL so that the forward directions thereof are opposite to each other. Similarly, two ESD protection elements 30C are provided for each of the GDM wiring lines ML. The two ESD protection elements 30C are connected in parallel between the GDM wiring line ML and the common wiring line CL so that the forward directions thereof are opposite to each other. The two ESD protection elements 30 are connected in parallel between the two wiring lines so that the forward directions thereof are opposite to each other, which may be collectively referred to as an “ESD protection circuit”.

In the active matrix substrate 100, when static electricity enters any one of the wiring lines from the outside, the gate of the ESD protection element 30 electrically connected to the wiring line is opened, and the charge is sequentially diffused toward another wiring line via the common wiring line CL, so that the damage to the pixel TFT 10 and the circuit TFT 20 due to the static electricity can be suppressed.

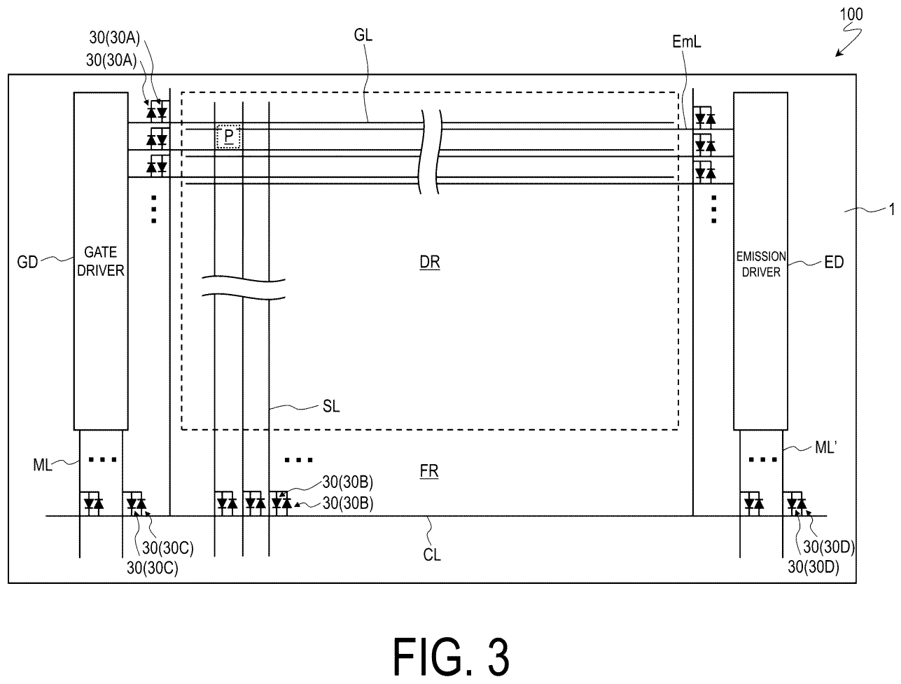

Subsequently, an overview of a structure of the active matrix substrate 100 according to the present embodiment will be described with reference to FIG. 3. FIG. 3 is a schematic view illustrating an example of a planar structure of the active matrix substrate 100 in a case in which the active matrix substrate 100 is for an organic EL display device. In the following, description will focus on points where the structure illustrated in FIG. 3 differs from the structure illustrated in FIG. 1.

In the example illustrated in FIG. 3, a plurality of light emission control wiring lines EmL are provided on the substrate 1 in addition to the plurality of gate wiring lines GL and the plurality of source wiring lines SL. The plurality of light emission control wiring lines EmL each extend in the row direction.

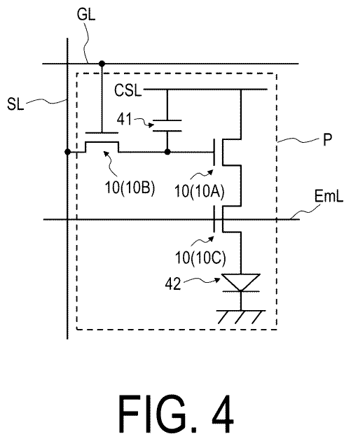

FIG. 4 illustrates an example of the equivalent circuit of the pixel region P in the active matrix substrate 100 illustrated in FIG. 3. As illustrated in FIG. 4, each pixel region P includes three pixel TFTs 10, a capacitance element (holding capacitor) 41, and an OLED (organic light emitting diode) 42.

The three pixel TFTs 10 are, to be specific, a drive pixel TFT 10A, a selection pixel TFT 10B, and a light emission control pixel TFT 10C.

The gate electrode of the selection pixel TFT 10B is electrically connected to the gate wiring line GL. One of the source electrode and the drain electrode of the selection pixel TFT 10B is electrically connected to the source wiring line SL, and the other is electrically connected to the gate electrode of the drive pixel TFT 10A.

One of the source electrode and the drain electrode of the drive pixel TFT 10A is electrically connected to a current supply line CSL, and the other is electrically connected to one of the source electrode and the drain electrode of the light emission control pixel TFT 10C.

The other of the source electrode and the drain electrode of the light emission control pixel TFT 10C is electrically connected to the OLED 42. The gate electrode of the light emission control pixel TFT 10C is electrically connected to the light emission control wiring line EmL.

One of a pair of electrodes constituting the capacitance element 41 is electrically connected to the gate electrode of the drive pixel TFT 10A, and the other is electrically connected to the current supply line CSL.

In the non-display region FR of the active matrix substrate 100 illustrated in FIG. 3, an emission driver (light emission control wiring line drive circuit) ED is disposed in addition to the gate driver GD and the source driver (not illustrated). Each of the light emission control wiring lines EmL is connected to a respective one of a plurality of output terminals of the emission driver ED.

Here, the emission driver ED is integrally (monolithically) formed on the substrate 1. In the display region DR, a plurality of wiring lines (hereinafter, referred to as “EDM wiring lines”) ML′ for supplying signals to the emission driver ED are provided on the substrate 1.

The plurality of ESD protection elements 30 disposed in the non-display region FR include ESD protection elements 30D electrically connected to the respective EDM wiring lines ML′ and the common wiring line CL, in addition to the ESD protection elements 30A electrically connected to the respective gate wiring lines GL and the common wiring line CL, the ESD protection elements 30B electrically connected to the respective source wiring lines SL and the common wiring line CL, and the ESD protection elements 30C electrically connected to the respective GDM wiring lines ML and the common wiring line CL.

In the active matrix substrate 100 illustrated in FIG. 3, the ESD protection element 30 can also suppress the damage to the pixel TFT 10 and the circuit TFT 20 due to static electricity.

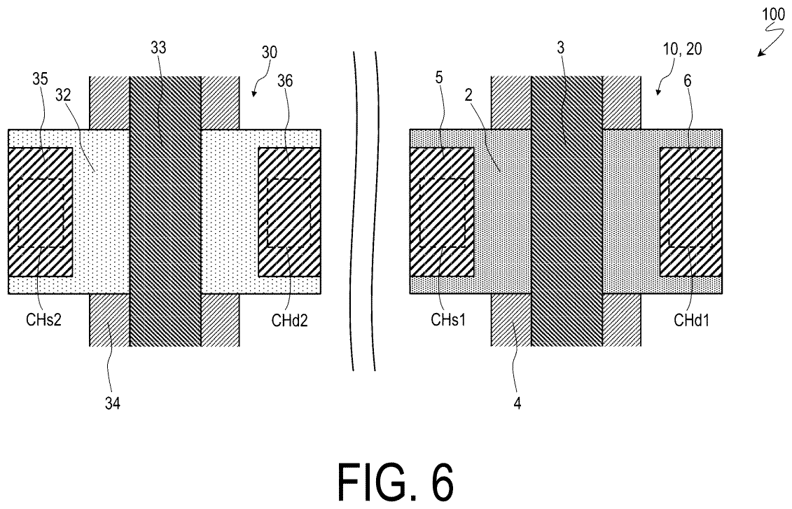

The structure of the oxide semiconductor TFT (the pixel TFT 10, the circuit TFT 20, and the ESD protection element 30 described above) included in the active matrix substrate 100 will be described with reference to FIGS. 5 and 6. The oxide semiconductor TFT of the active matrix substrate 100 has the top gate structure or the double gate structure. Hereinafter, the double gate structure will be described as an example. FIG. 5 and FIG. 6 are a cross-sectional view and a plan view schematically illustrating part of the active matrix substrate 100. In each of FIGS. 5 and 6, the structures of the pixel TFT 10 and the circuit TFT 20 are illustrated on the right side of the figure, and the structure of the ESD protection element 30 is illustrated on the left side of the figure.

In the present embodiment, the pixel TFT 10 and the circuit TFT 20 have substantially the same structure. The pixel TFT 10 and the circuit TFT 20 each include an oxide semiconductor layer 2, an upper gate electrode 3, a lower gate electrode 4, a source electrode 5, and a drain electrode 6. The pixel TFT 10 and the circuit TFT 20 each further include an upper gate insulating layer 7 and a lower gate insulating layer 8.

The oxide semiconductor layer 2 includes a channel region 2c, and a source contact region 2s and a drain contact region 2d that are located respectively on both sides of the channel region 2c. The source contact region 2s and the drain contact region 2d may be low-resistive regions having specific resistance lower than that of the channel region 2c. The low-resistive region can be formed by, for example, subjecting the oxide semiconductor layer 2 to the resistance reduction processing using the upper gate electrode 3 as a mask.

The upper gate electrode 3 is located above the oxide semiconductor layer 2. The upper gate electrode 3 faces the channel region 2c via the upper gate insulating layer 7. The upper gate electrode 3 of the pixel TFT 10 is electrically connected to the corresponding gate wiring line GL.

The upper gate insulating layer 7 is disposed between the oxide semiconductor layer 2 and the upper gate electrode 3. The upper gate insulating layer 7 is provided at least on the channel region 2c.

The lower gate electrode 4 is disposed between the substrate 1 and the oxide semiconductor layer 2. That is, the lower gate electrode 4 is located below the oxide semiconductor layer 2 and is disposed on the opposite side of the oxide semiconductor layer 2 from the upper gate electrode 3.

The lower gate insulating layer 8 is provided so as to cover the lower gate electrode 4, and is disposed between the lower gate electrode 4 and the oxide semiconductor layer 2. The lower gate insulating layer 8 includes a first layer 8a and a second layer 8b provided on the first layer 8a.

The source electrode 5 is electrically connected to the source contact region 2s of the oxide semiconductor layer 2. The drain electrode 6 is electrically connected to the drain contact region 2d of the oxide semiconductor layer 2. The source electrode 5 of the pixel TFT 10 is electrically connected to the corresponding source wiring line SL.

In the example illustrated in the figure, an interlayer insulating layer 9 is provided so as to cover the oxide semiconductor layer 2, the upper gate insulating layer 7, and the upper gate electrode 3, and the source electrode 5 and the drain electrode 6 are provided on the interlayer insulating layer 9.

The interlayer insulating layer 9 has a source contact hole CHs1 exposing part of the source contact region 2s of the oxide semiconductor layer 2, and a drain contact hole CHd1 exposing part of the drain contact region 2d of the oxide semiconductor layer 2. The source electrode 5 is connected to the source contact region 2s in the source contact hole CHs1. The drain electrode 6 is connected to the drain contact region 2d in the drain contact hole CHd1.

In the example illustrated in the figure, the width of the lower gate electrode 4 along a channel length direction is larger than the width of the upper gate electrode 3 along the channel length direction, and the lower gate electrode 4 protrudes from the upper gate electrode 3 toward both sides (the source contact region 2s side and the drain contact region 2d side) in a plan view.

In the example illustrated in the figure, the upper gate insulating layer 7 is patterned so as not to at least partially cover a portion of the source contact region 2s not overlapping the source contact hole CHs and a portion of the drain contact region 2d not overlapping the drain contact hole CHd. Furthermore, in a plan view, the upper gate insulating layer 7 slightly protrudes from the upper gate electrode 3 toward the source contact region 2s side and the drain contact region 2d side. Hereinafter, a protrusion width W1 of the upper gate insulating layer 7 from the upper gate electrode 3 toward the source contact region 2s side is referred to as a “first protrusion width”, and a protrusion width W2 of the upper gate insulating layer 7 from the upper gate electrode 3 toward the drain contact region 2d side is referred to as a “second protrusion width”.

The ESD protection element 30 includes an oxide semiconductor layer 32, an upper gate electrode 33, a lower gate electrode 34, a source electrode 35, and a drain electrode 36. The ESD protection element 30 further includes an upper gate insulating layer 37 and a lower gate insulating layer 38.

The oxide semiconductor layer 32 includes a channel region 32c, and a source contact region 32s and a drain contact region 32d that are located respectively on both sides of the channel region 32c. The source contact region 32s and the drain contact region 32d may be low-resistive regions having specific resistance lower than that of the channel region 32c. The low-resistive region can be formed by, for example, subjecting the oxide semiconductor layer 32 to the resistance reduction processing using the upper gate electrode 33 as a mask.

The upper gate electrode 33 is located above the oxide semiconductor layer 32. The upper gate electrode 33 faces the channel region 32c via the upper gate insulating layer 37. The upper gate electrode 33 is formed in the same layer as the upper gate electrode 3 of the pixel TFT 10 and the circuit TFT 20.

The upper gate insulating layer 37 is disposed between the oxide semiconductor layer 32 and the upper gate electrode 33. The upper gate insulating layer 37 is provided at least on the channel region 32c.

The lower gate electrode 34 is disposed between the substrate 1 and the oxide semiconductor layer 32. That is, the lower gate electrode 34 is located below the oxide semiconductor layer 32, and is disposed on the opposite side of the oxide semiconductor layer 32 from the upper gate electrode 33. There are several possible modes of the electrical connection relationship of the lower gate electrode 34. Details thereof will be described below.

The lower gate insulating layer 38 is provided so as to cover the lower gate electrode 34, and is disposed between the lower gate electrode 34 and the oxide semiconductor layer 32.

The source electrode 35 is electrically connected to the source contact region 32s of the oxide semiconductor layer 32. The drain electrode 36 is electrically connected to the drain contact region 32d of the oxide semiconductor layer 32. The source electrode 35 and drain electrode 36 are formed in the same layer as the source electrode 5 of the pixel TFT 10 and the circuit TFT 20.

The oxide semiconductor layer 32, the upper gate insulating layer 37, and the upper gate electrode 33 are covered with the interlayer insulating layer 9, and the source electrode 35 and the drain electrode 36 are disposed on the interlayer insulating layer 9.

The interlayer insulating layer 9 has a source contact hole CHs2 exposing part of the source contact region 32s of the oxide semiconductor layer 32, and a drain contact hole CHd2 exposing part of the drain contact region 32d of the oxide semiconductor layer 32. The source electrode 35 is connected to the source contact region 32s in the source contact hole CHs2. The drain electrode 36 is connected to the drain contact region 32d in the drain contact hole CHd2.

The upper gate electrode 33 and the source electrode 35 of the ESD protection element 30 are electrically connected to each other. That is, the ESD protection element 30 is diode-connected.

In the example illustrated, the width of the lower gate electrode 34 along the channel length direction is larger than the width of the upper gate electrode 33 along the channel length direction, and the lower gate electrode 34 protrudes from the upper gate electrode 33 toward both sides (the source contact region 32s side and the drain contact region 32d side) in a plan view.

In the example illustrated in the figure, the upper gate insulating layer 37 is patterned so as not to at least partially cover a portion of the source contact region 32s not overlapping the source contact hole CHs2 and a portion of the drain contact region 32d not overlapping the drain contact hole CHd2. Further, in a plan view, the upper gate insulating layer 37 slightly protrudes from the upper gate electrode 33 toward the source contact region 32s side and the drain contact region 32d side. The first protrusion width W1 of the upper gate insulating layer 37 of the ESD protection element 30 is larger than the first protrusion width W1 of the upper gate insulating layer 7 of the pixel TFT 10 and the circuit TFT 20, and the second protrusion width W2 of the upper gate insulating layer 37 of the ESD protection element 30 is larger than the second protrusion width W2 of the upper gate insulating layer 7 of the pixel TFT 10 and the circuit TFT 20.

The oxide semiconductor layer 32 of the ESD protection element 30 is formed in a layer separated from the oxide semiconductor layer 2 of the pixel TFT 10 and the circuit TFT 20. The oxide semiconductor layer 32 of the ESD protection element 30 has a mobility lower than the mobility of the oxide semiconductor layer 2 of the pixel TFT 10 and the circuit TFT 20.

The upper gate insulating layer 37 of the ESD protection element 30 includes a first layer 37a and a second layer 37b provided on the first layer 37a. The first layer 37a is formed in the same layer as the second layer 8b of the lower gate insulating layer 8 of the pixel TFT 10 and the circuit TFT 20. The second layer 37b is formed in the same layer as the upper gate insulating layer 7 of the pixel TFT 10 and the circuit TFT 20. The lower gate insulating layer 38 of the ESD protection element 30 is formed in the same layer as the first layer 8a of the lower gate insulating layer 8 of the pixel TFT 10 and the circuit TFT 20.

As described above, in the active matrix substrate 100 of the present embodiment, the oxide semiconductor layer 32 of the ESD protection element 30 is formed in a layer separated from the oxide semiconductor layer 2 of the pixel TFT 10 and the circuit TFT 20, and has a mobility lower than the mobility of the oxide semiconductor layer 2 in the pixel TFT 10 and the circuit TFT 20. As such, this suppresses the damage to the ESD protection element 30 due to an excessive current flowing through the ESD protection element 30 during the operation of the ESD protection element 30, and the decrease in the voltage of various signals flowing through the wiring line due to a leakage current of the ESD protection element 30.

Note that in order to suppress the decrease in the signal voltage due to the leakage current of the ESD protection element, it is conceivable to increase the channel length of the ESD protection element. However, in this case, the size of the ESD protection element increases. In the active matrix substrate 100 of the present embodiment, the leakage current can be reduced with a relatively short channel length, and therefore, the effect of reducing the size of the ESD protection element 30 can also be obtained.

In the active matrix substrate 100 of the present embodiment, the upper gate insulating layer 37 of the ESD protection element 30 has a layered structure including the first layer 37a and the second layer 37b provided on the first layer 37a and formed in the same layer as the upper gate insulating layer 7 of the pixel TFT 10 and the circuit TFT 20. Therefore, the thickness of the upper gate insulating layer 37 of the ESD protection element 30 is larger than the thickness of the upper gate insulating layer 7 of the pixel TFT 10 and the circuit TFT 20, and thus dielectric breakdown between the source and the gate in the ESD protection element 30 can be suppressed.

Furthermore, in the active matrix substrate 100 of the present embodiment, the first protrusion width W1 of the upper gate insulating layer 37 of the ESD protection element 30 is larger than the first protrusion width W1 of the upper gate insulating layer 7 of the pixel TFT 10 and the circuit TFT 20, and the second protrusion width W2 of the upper gate insulating layer 37 of the ESD protection element 30 is larger than the second protrusion width W2 of the upper gate insulating layer 7 of the pixel TFT 10 and the circuit TFT 20, so that the source-drain breakdown voltage of the ESD protection element 30 can be increased. This is because the resistance of the portion of the oxide semiconductor layer 32 covered with the upper gate insulating layer 37 is less likely to be reduced than the resistance of the portion not covered with the upper gate insulating layer 37, and thus the high voltage applied between the source and the drain is less likely to be concentrated on the channel region 32c due to the large first protrusion width W1 and the large second protrusion width W2.

In the active matrix substrate 100 of the present embodiment, the lower gate electrode 34 of the ESD protection element 30 protrudes from the upper gate electrode 33 toward both sides (the source contact region 32s side and the drain contact region 32d side). This makes it possible to increase the source-drain breakdown voltage of the ESD protection element 30.

Note that in the example illustrated in the figure, the lower gate electrode 4 of the pixel TFT 10 and the circuit TFT 20 also protrude from the upper gate electrode 3 toward both sides (the source contact region 2s side and the drain contact region 2d side). Therefore, the source-drain breakdown voltage of the pixel TFT 10 and the circuit TFT 20 can be increased. Further, by appropriately setting the protrusion width of the lower gate electrode 4 from the upper gate electrode 3, the mobility of the pixel TFT 10 and the circuit TFT 20 can be controlled and adjusted. Specifically, by increasing the protrusion width (for example, to 1 μm or more), the mobility of the pixel TFT 10 and the circuit TFT 20 can be further increased.

The active matrix substrate 100 may further include a demultiplexer (DEMUX) circuit (also referred to as an “SSD circuit”) that drives the source wiring line SL in a time-division manner. The DEMUX circuit is disposed in the non-display region FR. The DEMUX circuit may be formed monolithically on the substrate 1. In this case, the same structure as that of the circuit TFT 20 illustrated in FIGS. 5 and 6 may be adopted for the circuit TFT constituting the DEMUX circuit.

The composition, crystal structure, thickness, forming method, and the like of each of the oxide semiconductor layers 2 and 32 are not particularly limited.

The oxide semiconductor layers 2 and 32 may have different compositions. Here, “having different compositions” means that each of the layers contains different types of metal elements or metal elements with different composition ratios. As an example, the oxide semiconductor layers 2 and 32 each include In and/or Sn, and a sum of atomic ratios of In and Sn to all metal elements in the oxide semiconductor layer 32 may be smaller than a sum of atomic ratios of In and Sn to all metal elements in the oxide semiconductor layer 2.

Alternatively, both the oxide semiconductor layers 2 and 32 may be an In—Ga—Zn—O based oxide semiconductor layer, and an atomic ratio of In in the oxide semiconductor layer 32 may be less than an atomic ratio of In in the oxide semiconductor layer 2. In this case, in one of the oxide semiconductor layers 2 and 32, the atomic ratio of In to all metal elements and an atomic ratio of Zn to all metal elements may be the same.

Further, the oxide semiconductor layer 2 may contain Sn, and the oxide semiconductor layer 32 does not need to contain Sn. Alternatively, the oxide semiconductor layer 32 may contain Sn at a lower concentration than the oxide semiconductor layer 2. In other words, an atomic ratio of Sn to all metal elements in the oxide semiconductor layer 32 may be less than an atomic ratio of Sn to all metal elements in the oxide semiconductor layer 2.

As the oxide semiconductor layer 32, for example, an In—Ga—Zn—O based semiconductor layer (such as In:Ga:Zn=1:1:1) can be used. As the oxide semiconductor layer 2, for example, an In—Ga—Zn—O based semiconductor layer (such as In:Ga:Zn=3:1:2), an In—Sn—Zn—O based semiconductor layer, an In—Al—Sn—Zn—O based semiconductor layer, an In—W—Zn—O based semiconductor layer, an In—Sn—O based semiconductor layer, an In—Zn—O based semiconductor layer, an In—Ga—Sn—O based semiconductor layer, an In—Sn—Ti—Zn—O based semiconductor layer, or the like can be used.

Further, the oxide semiconductor layers 2 and 32 may have different crystal structures from each other. For example, one of the oxide semiconductor layers 2 and 32 may be an amorphous oxide semiconductor layer, and the other may be a crystalline oxide semiconductor layer containing a crystalline portion.

Even when the ratio of each metal element of the oxide semiconductor layer 2 and the ratio of each metal element of the oxide semiconductor layer 32 are the same, the mobilities of these oxide semiconductor layers can be made different from each other by changing a film formation method or film formation conditions. For example, when forming the oxide semiconductor layers having the same ratio of each metal element as the oxide semiconductor layers 2 and 32 by sputtering, the atmosphere in a chamber (for example, the flow ratio of oxygen and Ar supplied to the chamber) may be different between these oxide semiconductor layers.

Specifically, when forming the oxide semiconductor layer 32, the flow ratio of oxygen to Ar may be set to be large (for example, 80%), and when forming the oxide semiconductor layer 2, the flow ratio of oxygen to Ar may be set smaller than the oxide semiconductor layer 32 (for example, 20%). As a result, the mobility of the oxide semiconductor layer 32 can be made lower than that of the oxide semiconductor layer 2.

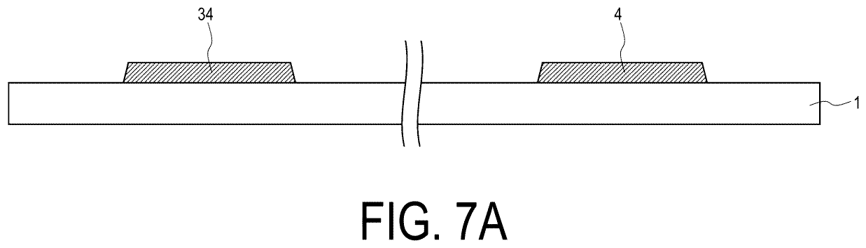

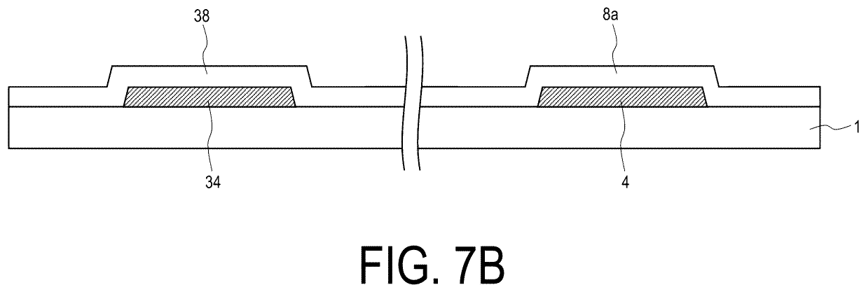

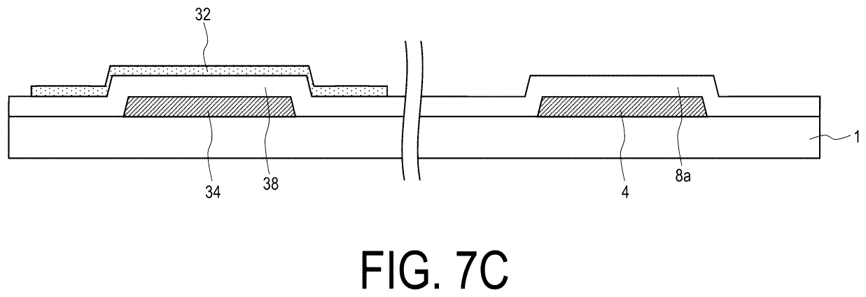

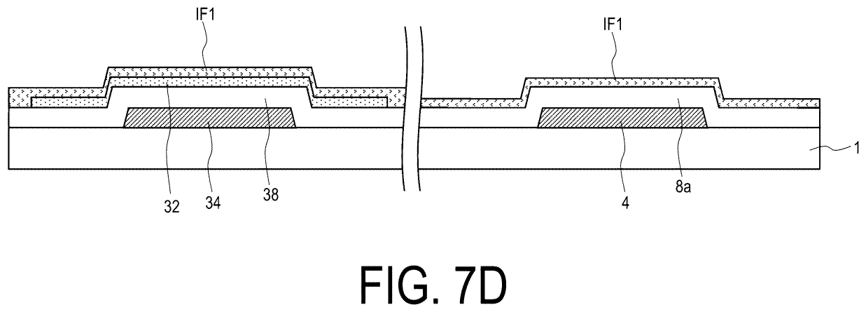

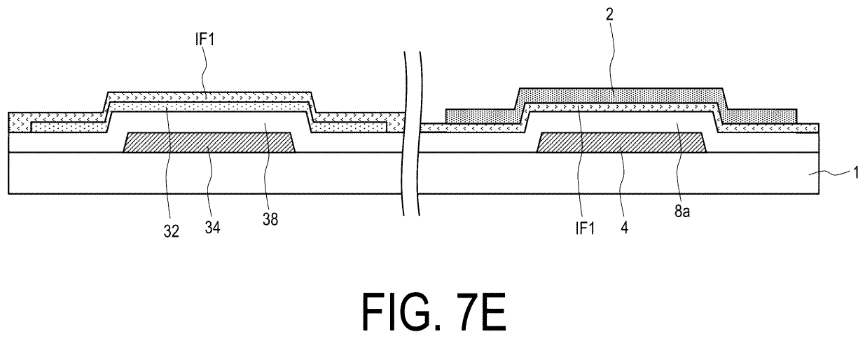

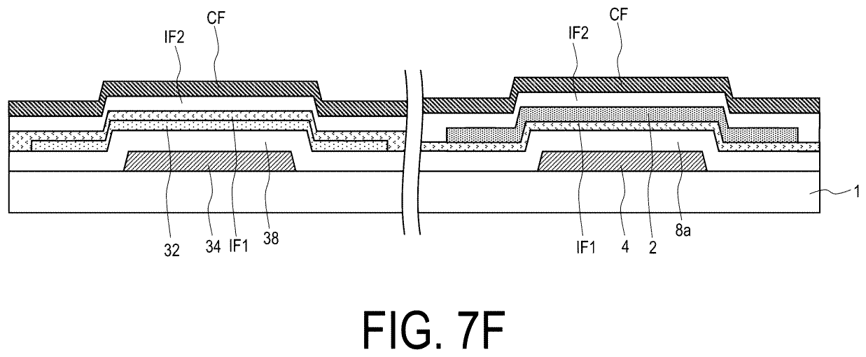

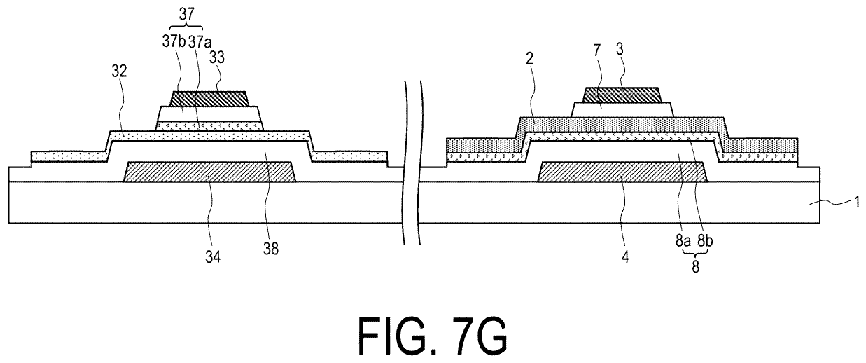

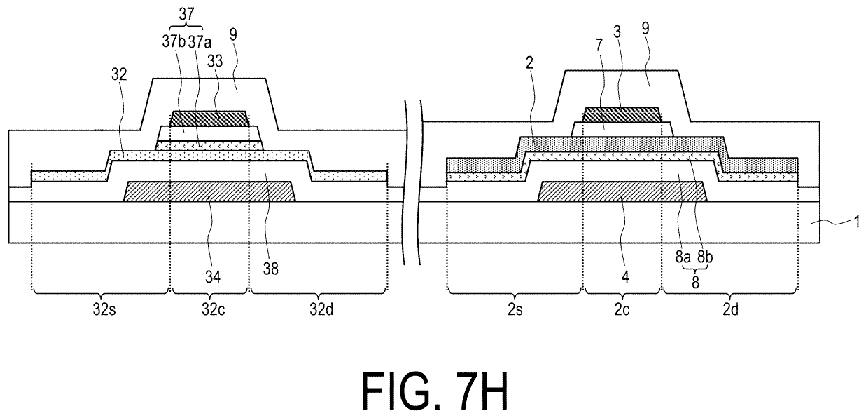

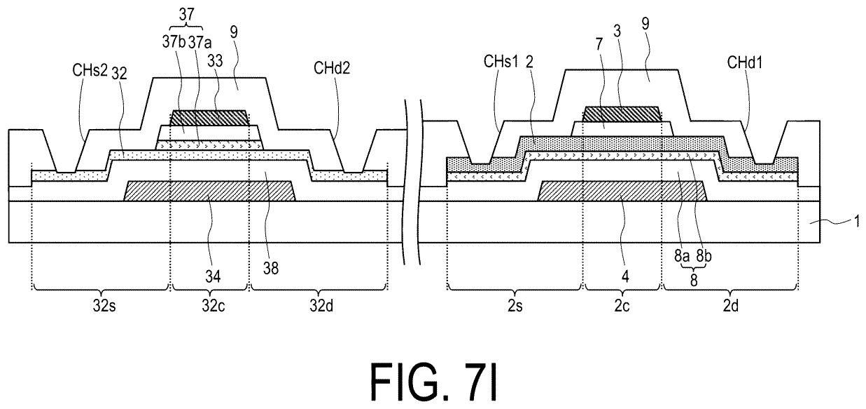

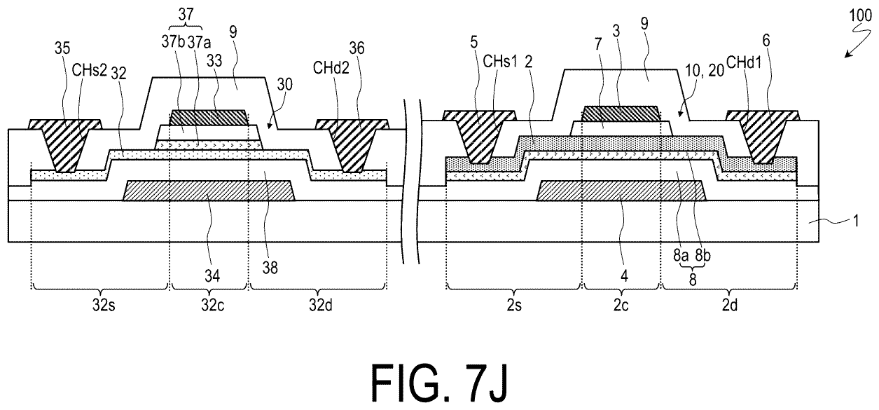

Here, the method of manufacturing the active matrix substrate 100 will be described with reference to FIG. 7A to FIG. 7J. FIG. 7A to FIG. 7J are process cross-sectional views for explaining the method of manufacturing the active matrix substrate 100.

First, as illustrated in FIG. 7A, the lower gate electrodes 4 and 34 are formed on the substrate 1. Specifically, the lower gate electrodes 4 and 34 can be formed by forming a lower gate conductive film (thickness of, for example, 50 nm or more and 500 nm or less) on the substrate 1 having insulating properties by a sputtering method or the like, and then patterning the lower gate conductive film.

A glass substrate, a plastic substrate (resin substrate) having heat resistance, or the like can be used as the substrate 1, for example.

As the lower gate conductive film, for example, a metal film including an element selected from aluminum (Al), chromium (Cr), copper (Cu), tantalum (Ta), titanium (Ti), molybdenum (Mo), or tungsten (W), or an alloy film including these elements as components can be used. In addition, a layered film including a plurality of films of these films may be used. Here, a metal film or an alloy film containing Cu or Al is used as the lower gate conductive film.

Next, as illustrated in FIG. 7B, the first layer 8a of the lower gate insulating layer 8 and the lower gate insulating layer 38 are formed so as to cover the lower gate electrodes 4 and 34. The first layer 8a of the lower gate insulating layer 8 and the lower gate insulating layer 38 are formed by CVD, for example. The thickness of the first layer 8a of the lower gate insulating layer 8 and the lower gate insulating layer 38 is, for example, in a range from 200 nm to 600 nm.

As the first layer 8a of the lower gate insulating layer 8 and the lower gate insulating layer 38, a silicon oxide (SiO₂) layer, a silicon nitride (SiNx) layer, a silicon oxynitride (SiOxNy; x>y) layer, a silicon nitride oxide (SiNxOy; x>y) layer, or the like can be used as appropriate. The first layer 8a of the lower gate insulating layer 8 and the lower gate insulating layer 38 may have a layered structure. For example, a silicon nitride layer, a silicon nitride oxide layer, or the like may be formed on the substrate 1 side (lower layer) in order to prevent diffusion of impurities and the like from the substrate 1, and a silicon oxide layer, a silicon oxynitride layer, or the like may be formed on a layer (upper layer) thereof in order to ensure insulating properties.

Subsequently, as illustrated in FIG. 7C, the oxide semiconductor layer 32 for the ESD protection element 30 (i.e., having relatively lower mobility) is formed on the lower gate insulating layer 38. Specifically, first, the oxide semiconductor layer 32 can be formed by depositing an oxide semiconductor film by using a sputtering method and then patterning the oxide semiconductor film. Here, an In—Ga—Zn—O based semiconductor film (for example, In:Ga:Zn=1:1:1 or 4:2:4) having a thickness of 40 nm is used as the oxide semiconductor film. The patterning of the In—Ga—Zn—O based semiconductor film can be performed by, for example, wet etching using a PAN-based etching solution containing phosphoric acid, nitric acid, and acetic acid, or an oxalic acid-based etching solution.

Next, as illustrated in FIG. 7D, an insulating film IF1 that becomes the second layer 8b of the lower gate insulating layer 8 and the first layer 37a of the upper gate insulating layer 37 is deposited so as to cover the oxide semiconductor layer 32. The insulating film IF1 is deposited by CVD, for example. As a material of the insulating film IF1, a material similar to the first layer 8a of the lower gate insulating layer 8 and the lower gate insulating layer 38 can be used. Here, a silicon oxide film is formed as the insulating film IF1. When an oxide film such as a silicon oxide film is used as the insulating film IF1, oxidation deficits generated in the channel region can be reduced by the oxide film. The thickness of the insulating film IF1 is, for example, in a range from 20 nm to 200 nm.

Subsequently, as illustrated in FIG. 7E, the oxide semiconductor layer 2 for the pixel TFT 10 and the circuit TFT 20 (i.e., having a relatively high mobility) is formed on the insulating film IF1. Specifically, first, the oxide semiconductor layer 2 can be formed by depositing an oxide semiconductor film by using a sputtering method and then patterning the oxide semiconductor film. Here, as the oxide semiconductor film, an In—Ga—Zn—O based semiconductor film (for example, In:Ga:Zn=5:1:4) having a thickness of 35 nm is formed. Alternatively, a film containing Sn such as an In—Sn—Zn—O based semiconductor film (for example, In₂O₃—SnO₂—ZnO) having a thickness of 35 nm may be formed. The In—Sn—Zn—O based semiconductor film may be patterned by wet etching using the oxalic acid-based etching solution.

Next, as illustrated in FIG. 7F, an insulating film IF2 that becomes the upper gate insulating layer 7 and the second layer 37b of the upper gate insulating layer 37, and an upper gate conductive film CF that becomes the upper gate electrodes 3 and 33 are sequentially deposited on the insulating film IF1 and the oxide semiconductor layer 2.

The insulating film IF2 is deposited by CVD, for example. As the insulating film IF2, an insulating film similar to the insulating film IF1 can be used. The insulating film IF2 may be formed from the same material as or the different material from the insulating film IF1. Here, a silicon oxide film is formed as the insulating film IF2. The thickness of the insulating film IF2 is, for example, in a range from 80 nm to 250 nm.

The upper gate conductive film CF may be deposited by, for example, a sputtering method. The thickness of the upper gate conductive film CF is, for example, in a range from 50 nm to 500 nm. A conductive film similar to the lower gate conductive film can be used as the upper gate conductive film CF.

Subsequently, as illustrated in FIG. 7G, patterning of the upper gate conductive film CF and patterning of the insulating films IF2 and IF1 are sequentially performed. Thus, the upper gate electrodes 3 and 33 are formed from the upper gate conductive film CF, the upper gate insulating layer 7 and the second layer 37b of the upper gate insulating layer 37 are formed from the insulating film IF2, and the second layer 8b of the lower gate insulating layer 8 and the first layer 37a of the upper gate insulating layer 37 are formed from the insulating film IF1.

Thereafter, the resistance reduction processing may be performed on the oxide semiconductor layers 2 and 32. The resistance reduction processing is, for example, plasma processing. With the resistance reduction processing, regions of the oxide semiconductor layer 2 not overlapping the upper gate electrode 3 are low-resistive regions (the source contact region 2s and the drain contact region 2d) having a lower specific resistance than a region (the channel region 2c) overlapping the upper gate electrode 3. Similarly, regions of the oxide semiconductor layer 32 not overlapping the upper gate electrode 33 are low-resistive regions (the source contact region 32s and the drain contact region 32d) having a lower specific resistance than a region (the channel region 32c) overlapping the upper gate electrode 33. Note that the method of the resistance reduction processing is not limited to the processing exemplified here.

Next, as illustrated in FIG. 7H, the interlayer insulating layer 9 that covers the oxide semiconductor layers 2 and 32, the upper gate electrodes 3 and 33, and the like is formed. The interlayer insulating layer 9 can be formed, for example, by CVD. As the interlayer insulating layer 9, an inorganic insulating layer such as a silicon oxide (SiO₂) layer, a silicon nitride (SiNx) layer, a silicon oxynitride (SiOxNy; x>y) layer, or a silicon nitride oxide (SiNxOy; x>y) layer can be used in a single layer or in layers. The thickness of the interlayer insulating layer 9 is, for example, in a range from 200 nm to 700 nm. Here, a silicon oxide layer is used as the interlayer insulating layer 9.

Subsequently, as illustrated in FIG. 7I, the source contact holes CHs1 and CHs2, and the drain contact holes CHd1 and CHd2 are formed in the interlayer insulating layer 9. The source contact holes CHs1 and CHs2, and the drain contact holes CHd1 and CHd2 can be formed by, specifically, the photolithography process and the etching. The etching may be dry etching, for example.

Then, as illustrated in FIG. 7J, the source electrodes 5 and 35, and the drain electrodes 6 and 36 are formed on the interlayer insulating layer 9. Specifically, the source electrodes 5 and 35, and the drain electrodes 6 and 36 can be formed by forming a source conductive film (thickness of, for example, 50 nm or more and 500 nm or less) on the interlayer insulating layer 9, and then patterning the source conductive film. The patterning of the source conductive film can be performed, for example, by dry etching or wet etching. As the source conductive film, an element selected from aluminum (Al), chromium (Cr), copper (Cu), tantalum (Ta), titanium (Ti), molybdenum (Mo), and tungsten (W), or an alloy including these elements as components can be used, for example. For example, the source conductive film may have a triple-layer structure of titanium film-aluminum film-titanium film, or a triple-layer structure of molybdenum film-aluminum film-molybdenum film. Note that the source conductive film is not limited to the triple-layer structure, and may have a single-layer structure or a dual-layer structure, or a layered structure of four or more layers. Here, a layered film having a lower layer of a Ti film (thickness of 15 nm or more and 70 nm or less) and an upper layer of a Cu film (thickness of 200 nm or more and 400 nm or less) is used.

In this manner, the active matrix substrate 100 including the pixel TFT 10, the circuit TFT 20, and the ESD protection element 30 is obtained.

### Second Embodiment

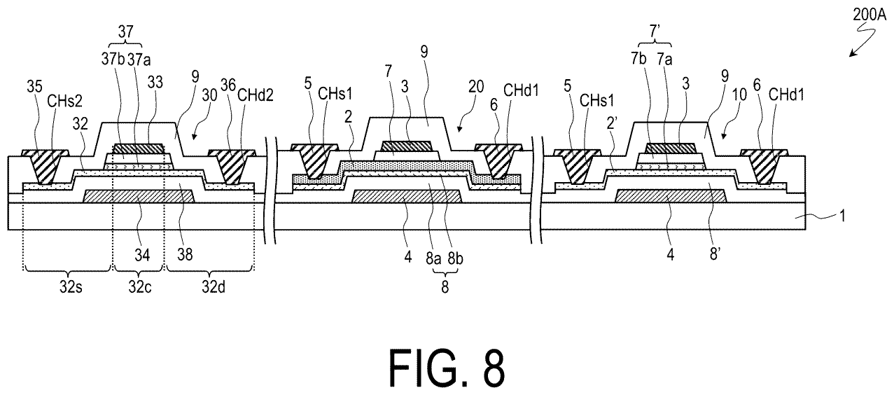

An active matrix substrate 200A in the present embodiment will be described with reference to FIG. 8. In the following, description will focus on points where the active matrix substrate 200A differs from the active matrix substrate 100 of the first embodiment. FIG. 8 is a cross-sectional view schematically illustrating part of the active matrix substrate 200A. In FIG. 8, the structure of the pixel TFT 10 is illustrated on the right side, the structure of the circuit TFT 20 is illustrated in the middle, and the structure of the ESD protection element 30 is illustrated on the left side.

The circuit TFT 20 and the ESD protection element 30 of the active matrix substrate 200A have the same structures as the circuit TFT 20 and the ESD protection element 30 of the active matrix substrate 100 of the first embodiment, respectively. In contrast, the pixel TFT 10 of the active matrix substrate 200A has a structure different from that of the pixel TFT 10 of the active matrix substrate 100 of the first embodiment.

An oxide semiconductor layer 2′ in the pixel TFT 10 of the active matrix substrate 200A is formed in a layer separated from the oxide semiconductor layer 2 in the circuit TFT 20, and is formed in the same layer as the oxide semiconductor layer 32 of the ESD protection element 30. Therefore, the oxide semiconductor layer 2′ of the pixel TFT 10 has a mobility lower than that of the oxide semiconductor layer 2 of the circuit TFT 20.

An upper gate insulating layer 7′ of the pixel TFT 10 includes a first layer 7a and a second layer 7b provided on the first layer 7a. The first layer 7a is formed in the same layer as the second layer 8b of the lower gate insulating layer 8 of the circuit TFT 20. The second layer 7b is formed in the same layer as the upper gate insulating layer 7 of the circuit TFT 20. That is, the upper gate insulating layer 7′ of the pixel TFT 10 has the same layered structure as the upper gate insulating layer 37 of the ESD protection element 30.

A lower gate insulating layer 8′ of the pixel TFT 10 is formed in the same layer as the first layer 8a of the lower gate insulating layer 8 of the circuit TFT 20. That is, the lower gate insulating layer 8′ of the pixel TFT 10 has the same structure as the lower gate insulating layer 38 of the ESD protection element 30.

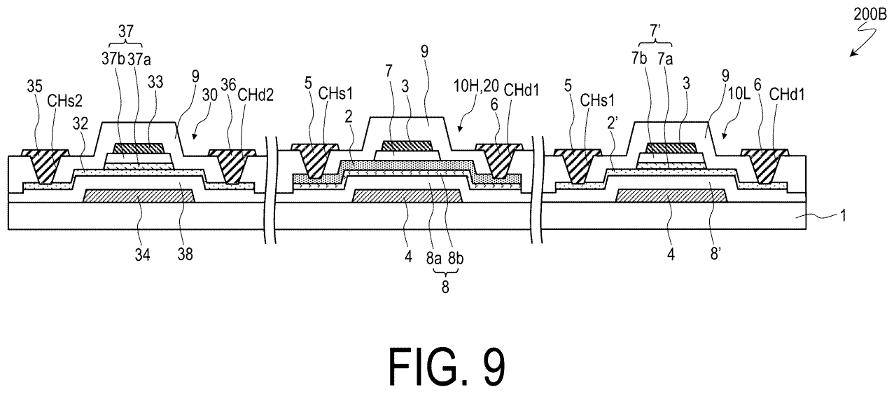

Another active matrix substrate 200B in the present embodiment will be described with reference to FIG. 9. FIG. 9 is a cross-sectional view schematically illustrating part of the active matrix substrate 200B.

The active matrix substrate 200B illustrated in FIG. 9 is for an organic EL display device, and a plurality of pixel TFTs are provided in each pixel region P. Some pixel TFTs 10H of the plurality of pixel TFTs have the same structure as the pixel TFT 10 of the active matrix substrate 100 of the first embodiment, and other pixel TFTs 10L have the same structure as the pixel TFT 10 of the active matrix substrate 200A illustrated in FIG. 8. Therefore, the former pixel TFT 10H has a relatively high mobility, and the latter pixel TFT 10L has a relatively low mobility.

For example, in the pixel circuit illustrated in FIG. 4, from the viewpoint of current control and in order to suitably perform multi-gray scale display, it is preferable that the Vg (gate voltage)-Id (drain current) characteristic of the drive pixel TFT 10A be gentle (that is, not steep) to some extent. On the other hand, the selection pixel TFT 10B preferably has a high mobility (i.e., a large ON-current). Therefore, it is preferable that the selection pixel TFT 10B be the pixel TFT 10H having a relatively high mobility and the drive pixel TFT 10A be the pixel TFT 10L having a relatively low mobility. The light emission control pixel TFT 10C is preferably the pixel TFT 10H having a relatively high mobility.

The active matrix substrates 200A and 200B may also obtain the same effect as the active matrix substrate 100 of the first embodiment.

### Third Embodiment

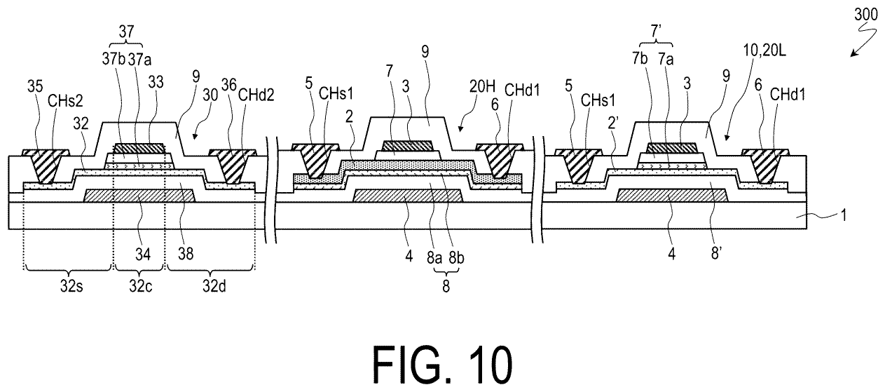

An active matrix substrate 300 in the present embodiment will be described with reference to FIG. 10. FIG. 10 is a cross-sectional view schematically illustrating part of the active matrix substrate 300. In the following, description will focus on points where the active matrix substrate 300 differs from the active matrix substrate 200A of the second embodiment.

In the active matrix substrate 300 of the present embodiment, some circuit TFTs 20H of the plurality of circuit TFTs have the same structure as the circuit TFT 20 of the active matrix substrate 200A of the second embodiment, and other circuit TFTs 20L have the same structure as the pixel TFT 10 of the active matrix substrate 200A of the second embodiment. Therefore, the former circuit TFT 20H has a relatively high mobility, and the latter circuit TFT 20L has a relatively low mobility.

The circuit TFT 20H having a relatively high mobility may be, for example, an output TFT of a gate driver GD or an output TFT of an emission driver ED. The circuit TFT 20L having a relatively low mobility may be, for example, a switching TFT of the gate driver GD or a switching TFT of the emission driver ED.

### Lower Gate Electrode

The lower gate electrode of an oxide semiconductor TFT included in the active matrix substrate according to the embodiment of the disclosure can have any one of the following configurations A to E, for example. When an active matrix substrate includes a DEMUX circuit, the same applies to the lower gate electrode of the oxide semiconductor TFT (circuit TFT) constituting the DEMUX circuit.

### Configuration A

In this configuration, the lower gate electrode is electrically connected to the upper gate electrode.

### Configuration B

In this configuration, the lower gate electrode is omitted. That is, the oxide semiconductor TFT has a top gate structure.

### Configuration C

In this configuration, a predetermined fixed potential is applied to the lower gate electrode.

### Configuration D

In this configuration, the lower gate electrode is electrically connected to a source electrode or a drain electrode.

### Configuration E

In this configuration, the lower gate electrode is electrically floating together with the upper gate electrode, and is capacitively coupled to the reduced resistance region of an oxide semiconductor layer.

Here, which of the configurations A to E is preferable in a case in which the active matrix substrate is for an organic EL display device and in a case in which the active matrix substrate is for a liquid crystal display device will be described.

### Active Matrix Substrate for Organic EL Display Device

In the active matrix substrate for the organic EL display device, from the viewpoint of suppressing damage to the ESD protection element 30 due to ESD, the lower gate electrode 34 of the ESD protection element 30 preferably has the configuration B rather than the configuration A, preferably has the configurations C and D rather than the configuration B, and preferably has the configuration E rather than the configurations C and D. That is, the configuration E is most preferable.

In addition, the configuration B is preferable to the configuration A for the lower gate electrode 4 of the selection pixel TFT 10B in the pixel circuit illustrated in FIG. 4. By omitting the lower gate electrode 4, a space-saving layout is possible. In addition, the lower gate electrode 4 of the drive pixel TFT 10A preferably has the configuration C or D from the viewpoint of suitably performing multi-gray scale display.

The lower gate electrode 4 of the output TFT of the gate driver GD and the output TFT of the emission driver ED preferably has the configuration A from the viewpoint of achieving high mobility. The lower gate electrode 4 of the switching TFT of the gate driver GD and the switching TFT of the emission driver ED preferably has the configuration A, C, or D from the viewpoint of increasing the threshold voltage to stably operate the gate driver GD and the emission driver ED.

### Active Matrix Substrate for Liquid Crystal Display Device

In the active matrix substrate for a liquid crystal display device, from the viewpoint of suppressing damage to the ESD protection element 30 due to ESD, the lower gate electrode 34 of the ESD protection element 30 preferably has the configurations C and D rather than the configuration A, and preferably has the configuration E rather than the configurations C and D. That is, the configuration E is most preferable. The configuration B is not preferable in that the reliability is lowered by the incident light from the backlight.

The lower gate electrode 4 of the pixel TFT 10 preferably has the configuration A or C from the viewpoint of ensuring reliability against the incident light from the backlight.

The lower gate electrode 4 of the output TFT of the gate driver GD preferably has the configuration A from the viewpoint of achieving a high mobility. The lower gate electrode 4 of the switching TFT of the gate driver GD preferably has the configuration A or C from the viewpoint of reliability against incident light from the backlight and stable operation of the gate driver GD by increasing the threshold voltage.

### Fourth Embodiment

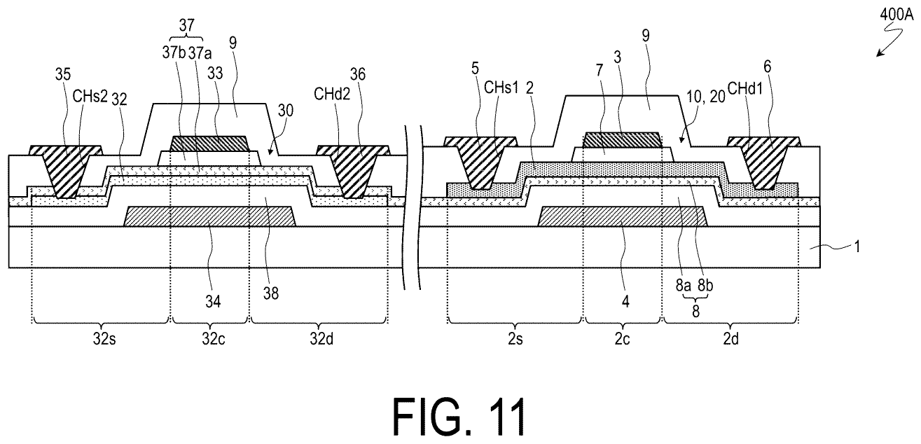

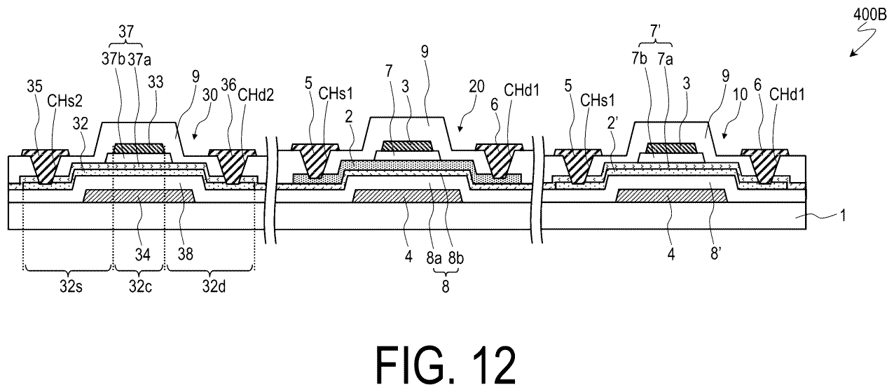

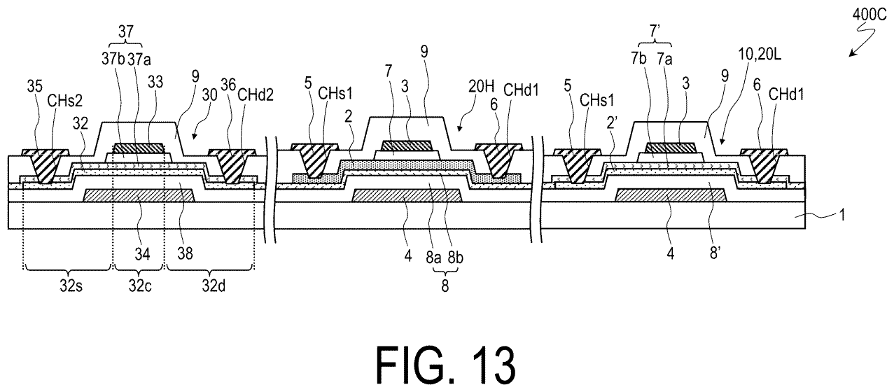

Active matrix substrates 400A, 400B, and 400C according to the present embodiment will be described with reference to FIGS. 11, 12, and 13. FIGS. 11, 12, and 13 are cross-sectional views schematically illustrating part of the active matrix substrates 400A, 400B, and 400C, respectively. In the following, description will focus on points where the active matrix substrates 400A, 400B, and 400C differ from the active matrix substrate 100 of the first embodiment, the active matrix substrate 200A of the second embodiment, and the active matrix substrate 300 of the third embodiment.

In the active matrix substrate 100 of the first embodiment, the active matrix substrate 200A of the second embodiment, and the active matrix substrate 300 of the third embodiment, as illustrated in FIGS. 5, 8, and 10, the upper gate insulating layer 37 of the ESD protection element 30 is patterned so as not to at least partially cover a portion of the source contact region 32s not overlapping the source contact hole CHs2 and a portion of the drain contact region 32d not overlapping the drain contact hole CHd2. In contrast, in the active matrix substrates 400A, 400B, and 400C, the first layer 37a of the upper gate insulating layer 37 of the ESD protection element 30 covers a portion of the source contact region 32s not overlapping the source contact hole CHs2 and a portion of the drain contact region 32d not overlapping the drain contact hole CHd2, as illustrated in FIGS. 11, 12, and 13.

Therefore, in the active matrix substrates 400A, 400B, and 400C, the source contact region 32s and the drain contact region 32d of the oxide semiconductor layer 32 of the ESD protection element 30 are less likely to have a reduced resistance than those in the active matrix substrate 100 of the first embodiment, the active matrix substrate 200A of the second embodiment, and the active matrix substrate 300 of the third embodiment, and thus the effect of suppressing damage to the ESD protection element 30 due to ESD is further enhanced.

Here, the method of manufacturing the active matrix substrate 400A will be described.

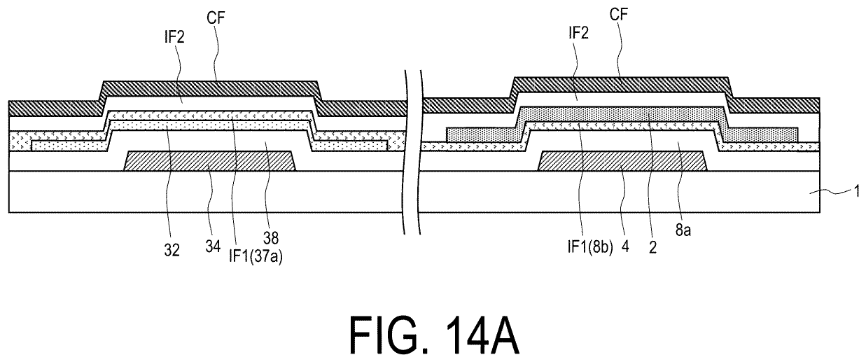

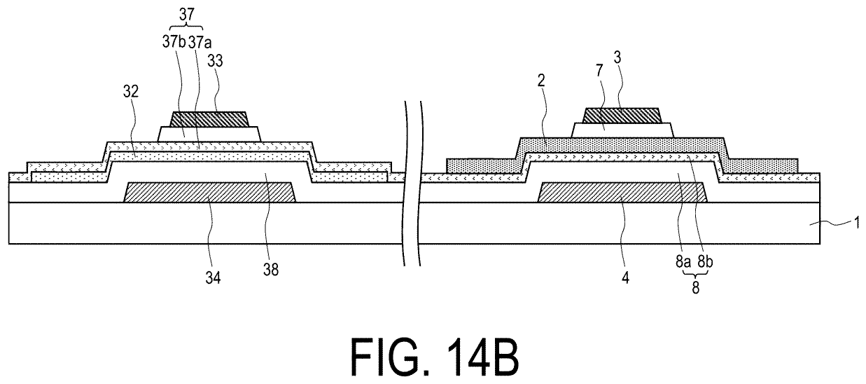

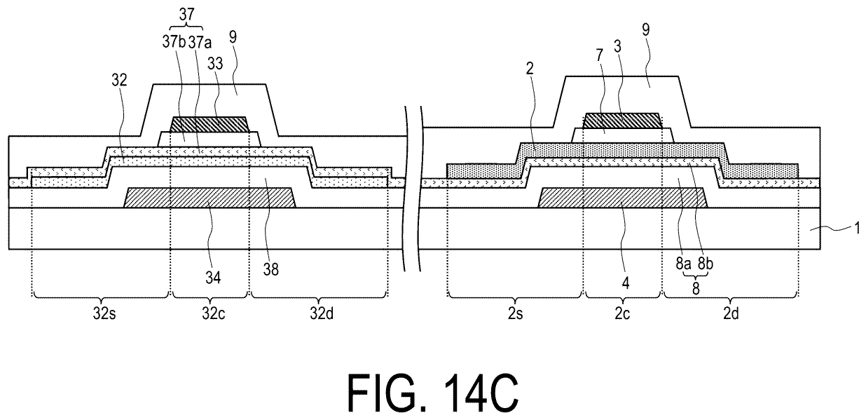

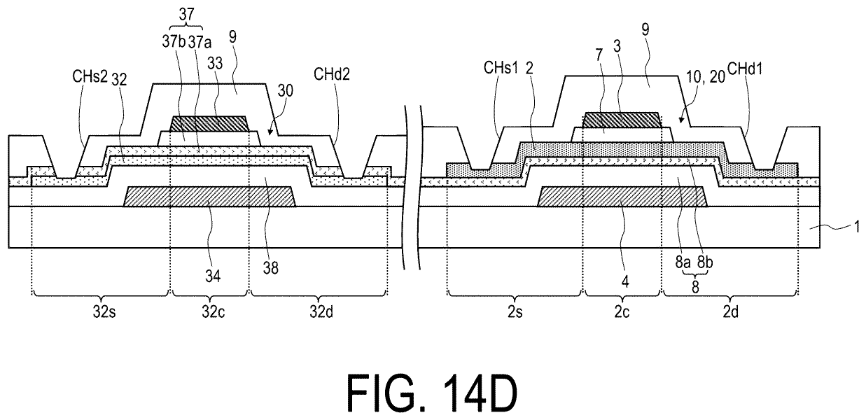

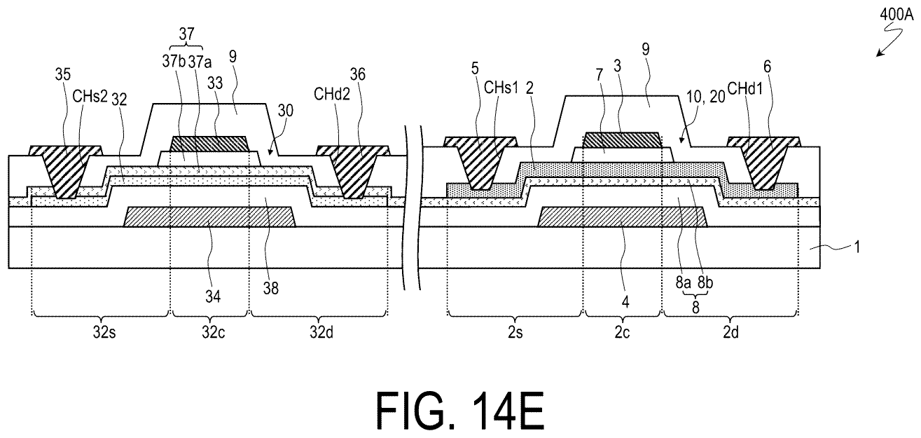

First, in the same manner as described with reference to FIGS. 7A to 7F, the followings are sequentially performed: on the substrate 1, the lower gate electrodes 4 and 34 are formed, the first layer 8a of the lower gate insulating layer 8, and the lower gate insulating layer 38 are formed, the oxide semiconductor layer 32 for the ESD protection element 30 (i.e., having a relatively low mobility) is formed, the insulating film IF1 is deposited, the oxide semiconductor layer 2 for the pixel TFT 10 and the circuit TFT 20 (i.e., having a relatively high mobility) is formed, the insulating film IF2 is deposited, and an upper gate conductive film CF is deposited. The FIG. 14A illustrates a state after deposition of the upper gate conductive film CF.

Next, as illustrated in FIG. 14B, patterning of the upper gate conductive film CF and patterning of the insulating film IF2 are sequentially performed. Thus, the upper gate electrodes 3 and 33 are formed from the upper gate conductive film CF, and the upper gate insulating layer 7 and the second layer 37b of the upper gate insulating layer 37 are formed from the insulating film IF2. In the present embodiment, the insulating film IF1 is not patterned at this time, and therefore, it can be said that the second layer 8b of the lower gate insulating layer 8 and the first layer 37a of the upper gate insulating layer 37 are formed at the time of deposition of the insulating film IF1.

Thereafter, the resistance reduction processing (for example, plasma processing) of the oxide semiconductor layers 2 and 32 may be performed. At this time, the source contact region 32s and the drain contact region 32d of the oxide semiconductor layer 32 are covered with the first layer 37a of the upper gate insulating layer 37, and thus are less likely to have a reduced resistance than in the case in which the source contact region 32s and the drain contact region 32d are exposed.

Next, as illustrated in FIG. 14C, the interlayer insulating layer 9 is formed to cover the oxide semiconductor layers 2 and 32, the upper gate electrodes 3 and 33, and the like.

Subsequently, as illustrated in FIG. 14D, the source contact hole CHs1 and the drain contact hole CHd1 are formed in the interlayer insulating layer 9, and the source contact hole CHs2 and the drain contact hole CHd2 are formed in the first layer 37a of the upper gate insulating layer 37 and the interlayer insulating layer 9.

Thereafter, as illustrated in FIG. 14E, the source electrodes 5 and 35, and the drain electrodes 6 and 36 are formed on the interlayer insulating layer 9.

In this manner, the active matrix substrate 400A of the present embodiment is obtained. The active matrix substrates 400B and 400C can be manufactured in the same manner.

### Fifth Embodiment

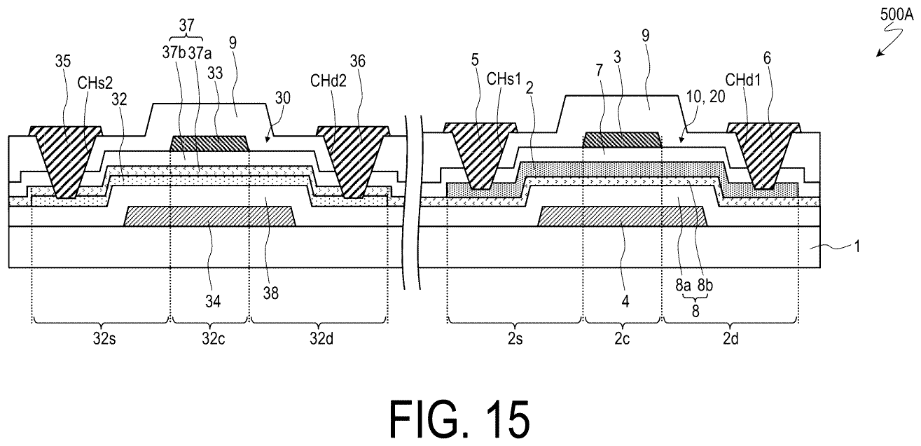

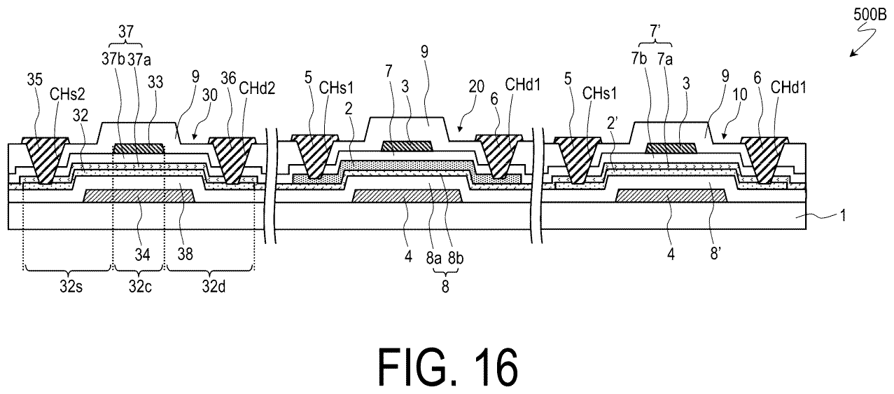

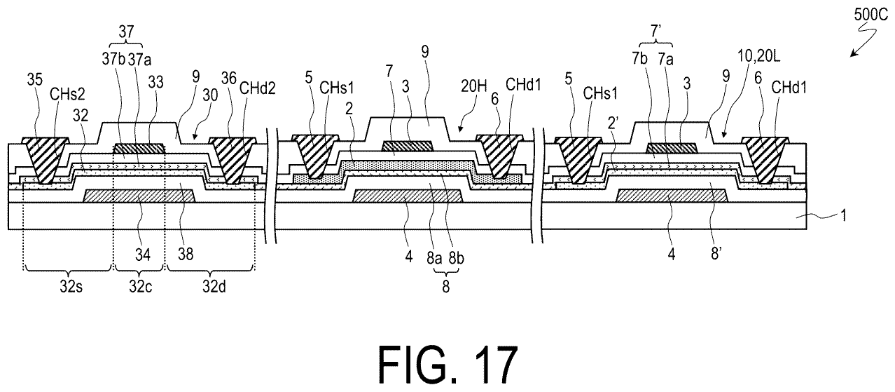

Active matrix substrates 500A, 500B, and 500C according to the present embodiment will be described with reference to FIGS. 15, 16, and 17. FIGS. 15, 16, and 17 are cross-sectional views schematically illustrating part of the active matrix substrates 500A, 500B, and 500C, respectively. In the following, description will focus on points where the active matrix substrates 500A, 500B, and 500C differ from the active matrix substrates 400A, 400B, and 400C of the fourth embodiment.

In the active matrix substrates 500A, 500B, and 500C, as illustrated in FIGS. 15, 16, and 17, not only the first layer 37a but also the second layer 37b of the upper gate insulating layer 37 of the ESD protection element 30 covers a portion of the source contact region 32s not overlapping the source contact hole CHs2 and a portion of the drain contact region 32d not overlapping the drain contact hole CHd2.

Therefore, in the active matrix substrates 500A, 500B, and 500C, the source contact region 32s and the drain contact region 32d of the oxide semiconductor layer 32 of the ESD protection element 30 are even less likely to have a reduced resistance than those in the active matrix substrates 400A, 400B, and 400C of the fourth embodiment, and thus the effect of suppressing damage to the ESD protection element 30 due to ESD is further increased.

Here, the method of manufacturing the active matrix substrate 500A will be described.

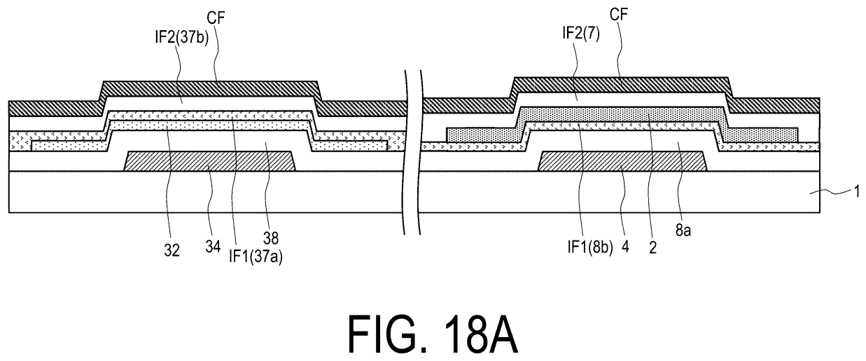

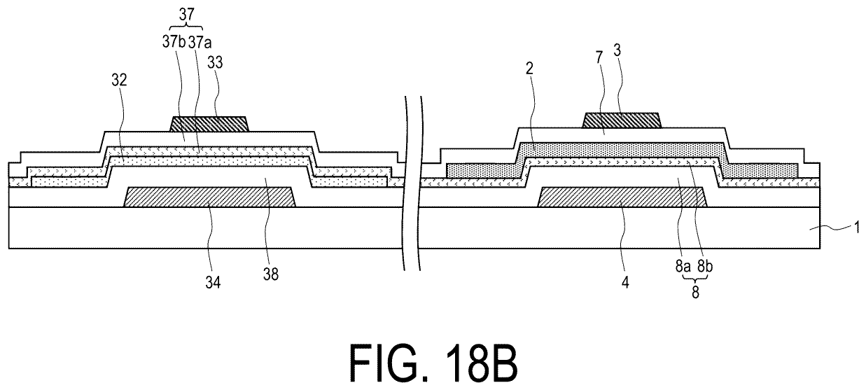

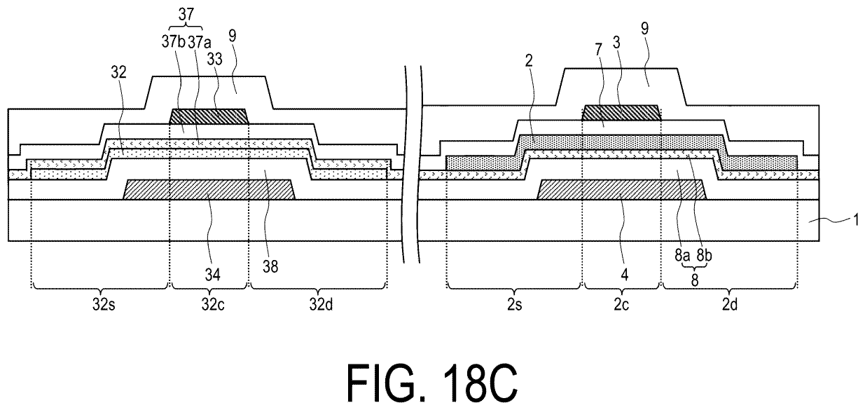

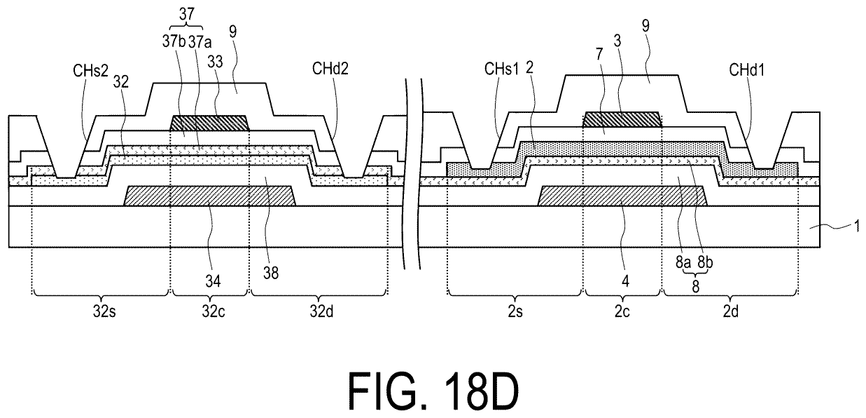

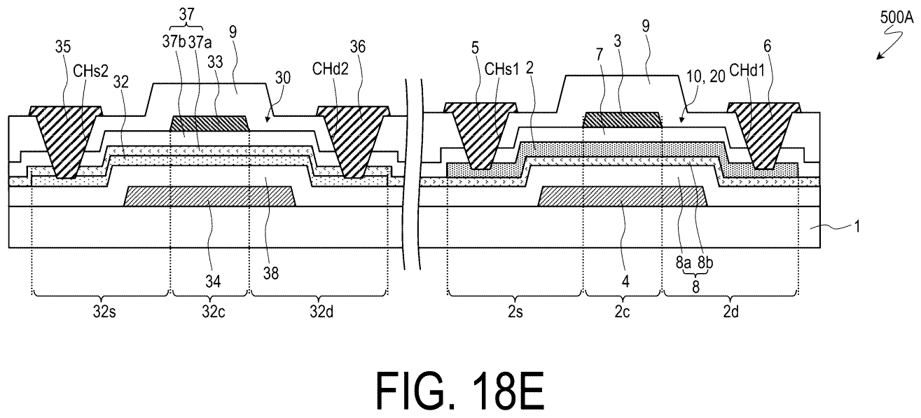

First, in the same manner as described with reference to FIGS. 7A to 7F, the followings are sequentially performed: on the substrate 1, the lower gate electrodes 4 and 34 are formed, the first layer 8a of the lower gate insulating layer 8, and the lower gate insulating layer 38 are formed, the oxide semiconductor layer 32 for the ESD protection element 30 (i.e., having a relatively low mobility) is formed, the insulating film IF1 is deposited, the oxide semiconductor layer 2 for the pixel TFT 10 and the circuit TFT 20 (i.e., having a relatively high mobility) is formed, the insulating film IF2 is deposited, and an upper gate conductive film CF is deposited. FIG. 18A illustrates a state after deposition of the upper gate conductive film CF.

Next, as illustrated in FIG. 18B, the upper gate conductive film CF is patterned. Thus, the upper gate electrodes 3 and 33 are formed from the upper gate conductive film CF. In the present embodiment, the insulating film IF1 and the insulating film IF2 are not patterned at this time. Therefore, it can be said that the second layer 8b of the lower gate insulating layer 8 and the first layer 37a of the upper gate insulating layer 37 are formed when the insulating film IF1 is deposited, and the upper gate insulating layer 7 and the second layer 37b of the upper gate insulating layer 37 are formed when the insulating film IF2 is deposited.

Thereafter, the resistance reduction processing (for example, plasma processing) of the oxide semiconductor layers 2 and 32 may be performed. At this time, the source contact region 32s and the drain contact region 32d of the oxide semiconductor layer 32 are covered with the first layer 37a and the second layer 37b of the upper gate insulating layer 37, and thus are less likely to have a reduced resistance than in the case in which the source contact region 32s and the drain contact region 32d are exposed or are covered with only the first layer 37a.

Next, as illustrated in FIG. 18C, the interlayer insulating layer 9 is formed to cover the oxide semiconductor layers 2 and 32, and the upper gate electrodes 3 and 33.

Subsequently, as illustrated in FIG. 18D, the source contact hole CHs1 and the drain contact hole CHd1 are formed in the upper gate insulating layer 7 and the interlayer insulating layer 9, and the source contact hole CHs2 and the drain contact hole CHd2 are formed in the first layer 37a and the second layer 37b of the upper gate insulating layer 37, and the interlayer insulating layer 9.

Thereafter, as illustrated in FIG. 18E, the source electrodes 5 and 35, and the drain electrodes 6 and 36 are formed on the interlayer insulating layer 9.

In this manner, the active matrix substrate 500A of the present embodiment is obtained. The active matrix substrates 500B and 500C can be manufactured in the same manner.

As described above, the configurations of the fourth and fifth embodiments are advantageous to the configurations of the first, second, and third embodiments in terms of suppressing damage to the ESD protection element 30. The configurations of the fourth and fifth embodiments are advantageous to the configurations of the first, second, and third embodiments in terms of high definition. These points will be described below.

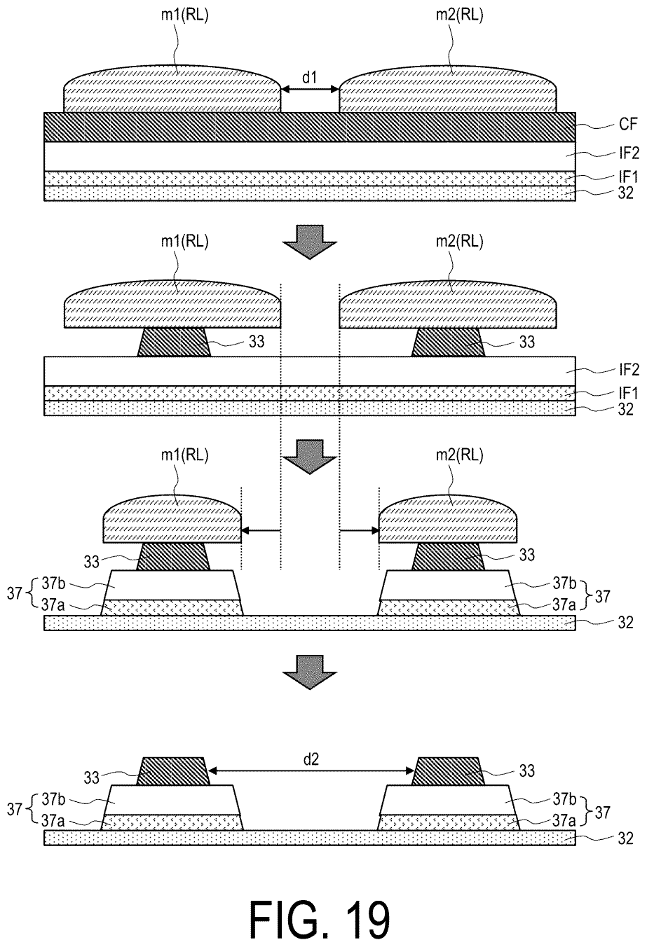

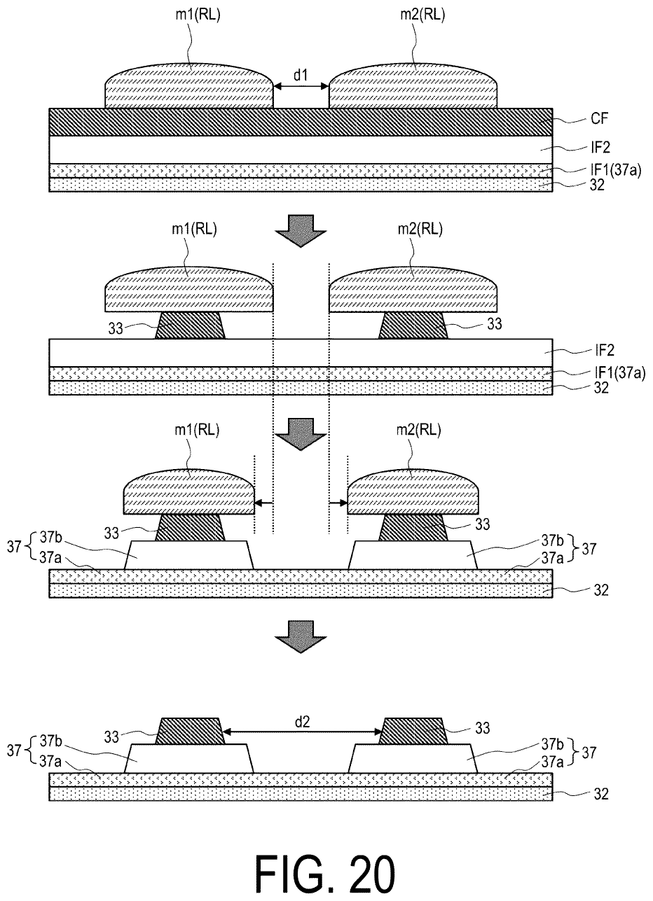

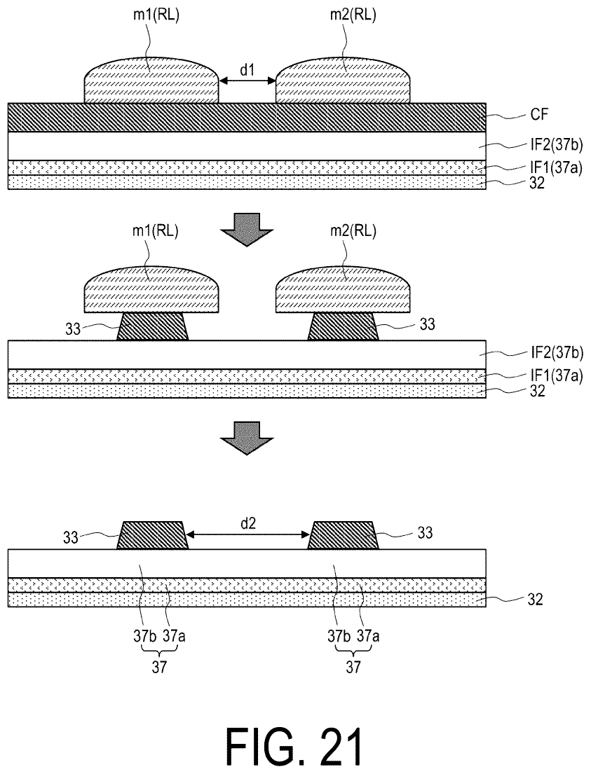

FIG. 19 is a diagram illustrating the steps described with reference to FIG. 7G in a subdivided manner in the method of manufacturing the active matrix substrate 100 of the first embodiment, and illustrates regions in which two ESD protection elements 30 adjacent to each other are formed. Note that in FIG. 19, the lower gate insulating layer 38, the lower gate electrode 34, and the substrate 1 are omitted, and the adjacent oxide semiconductor layers 32 are illustrated as being continuous (the same applies to FIGS. 20 and 21 described below).

When the step described with reference to FIG. 7G is performed, first, as illustrated in the uppermost stage (first stage) of FIG. 19, a resist layer RL is formed on the upper gate conductive film CF. Specifically, first, a resist film is deposited on the upper gate conductive film CF, and the resist film is exposed to light by using a photomask, followed by development, and thus the resist layer RL can be formed. The resist layer RL includes a mask portion m1 located in a region corresponding to one of the two ESD protection elements 30 and a mask portion m2 located in a region corresponding to the other of the two ESD protection elements 30. A length d1 between the mask portion m1 and the mask portion m2 is set to a predetermined length or more so that the mask portion m1 and the mask portion m2 are not continuous with each other.

Next, as illustrated in a second stage of FIG. 19, wet etching is performed on the upper gate conductive film CF by using the resist layer RL as a mask. Thus, the upper gate electrode 33 is formed below each of the mask portions m1 and m2.

Subsequently, as illustrated in a third stage of FIG. 19, dry etching is performed on the insulating films IF2 and IF1 by using the resist layer RL as a mask. As a result, the second layer 37b and the first layer 37a of the upper gate insulating layer 37 are formed below the upper gate electrode 33. At this time, as the dry etching proceeds, the edges of the mask portions m1 and m2 of the resist layer RL retreat.

Thereafter, as illustrated in the lowermost stage (fourth stage) of FIG. 19, the resist layer RL is peeled off. In this manner, the patterning of the upper gate conductive film CF, the insulating films IF2 and IF1 is completed. Note that before the resist layer RL is peeled off, the resistance reduction processing may be performed.

FIG. 20 is a diagram illustrating the steps described with reference to FIG. 14B in a subdivided manner in the method of manufacturing the active matrix substrate 400A of the fourth embodiment.

When the step described with reference to FIG. 14B is performed, first, as illustrated in the uppermost stage (first stage) of FIG. 20, the resist layer RL is formed on the upper gate conductive film CF. Specifically, first, a resist film is deposited on the upper gate conductive film CF, and the resist film is exposed to light by using a photomask, followed by development, and thus the resist layer RL can be formed. The resist layer RL includes the mask portion m1 located in a region corresponding to one of the two ESD protection elements 30 and the mask portion m2 located in a region corresponding to the other of the two ESD protection elements 30. The length d1 between the mask portion m1 and the mask portion m2 is set to a predetermined length or more so that the mask portion m1 and the mask portion m2 are not continuous with each other.

Next, as illustrated in a second stage of FIG. 20, wet etching is performed on the upper gate conductive film CF by using the resist layer RL as a mask. Thus, the upper gate electrode 33 is formed below each of the mask portions m1 and m2.

Subsequently, as illustrated in a third stage of FIG. 20, dry etching is performed on the insulating film IF2 by using the resist layer RL as a mask. As a result, the second layer 37b of the upper gate insulating layer 37 is formed below the upper gate electrode 33. At this time, as the dry etching proceeds, the edges of the mask portions m1 and m2 of the resist layer RL retreat.

Thereafter, as illustrated in the lowermost stage (fourth stage) of FIG. 20, the resist layer RL is peeled off. In this manner, the patterning of the upper gate conductive film CF and the insulating film IF2 is completed. Note that before the resist layer RL is peeled off, the resistance reduction processing may be performed.

In the active matrix substrate 400A (or 400B and 400C) of the fourth embodiment, the amount of recession of the edges of the mask portions m1 and m2 of the resist layer RL is smaller than the amount of recession in the active matrix substrate 100 of the first embodiment by the amount of dry etching not performed on the insulating film IF1. Therefore, in the configuration of the fourth embodiment, a distance d2 between the adjacent upper gate electrodes 33 can be reduced as compared with the configuration of the first embodiment, which is advantageous for high definition.

FIG. 21 is a diagram illustrating the steps described with reference to FIG. 18B in a subdivided manner in the method of manufacturing the active matrix substrate 500A of the fifth embodiment.

When the step described with reference to FIG. 18B is performed, first, as illustrated in the uppermost stage (first stage) of FIG. 21, the resist layer RL is formed on the upper gate conductive film CF. Specifically, first, a resist film is deposited on the upper gate conductive film CF, and the resist film is exposed to light by using a photomask, followed by development, and thus the resist layer RL can be formed. The resist layer RL includes the mask portion m1 located in a region corresponding to one of the two ESD protection elements 30 and the mask portion m2 located in a region corresponding to the other of the two ESD protection elements 30. The length d1 between the mask portion m1 and the mask portion m2 is set to a predetermined length or more so that the mask portion m1 and the mask portion m2 are not continuous with each other.

Next, as illustrated in a second stage in FIG. 21, wet etching is performed on the upper gate conductive film CF by using the resist layer RL as a mask. Thus, the upper gate electrode 33 is formed below each of the mask portions m1 and m2.

Thereafter, as illustrated in the lowermost stage (third stage) of FIG. 21, the resist layer RL is peeled off. In this manner, the patterning of the upper gate conductive film CF is completed. Note that before the resist layer RL is peeled off, the resistance reduction processing may be performed.

In the active matrix substrate 500A (or 500B and 500C) of the fifth embodiment, since dry etching is not performed on both the insulating films IF2 and IF1, the edges of the mask portions m1 and m2 of the resist layer RL are not retreated by the dry etching. Therefore, in the configuration of the fifth embodiment, the distance d2 between the adjacent upper gate electrodes 33 can be further reduced as compared with the configuration of the fourth embodiment, which is further advantageous for high definition.

### Oxide Semiconductor

An oxide semiconductor (also referred to as a metal oxide or an oxide material) included in the oxide semiconductor layer of an oxide semiconductor TFT may be an amorphous oxide semiconductor or a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

Materials, structures, and film formation methods of an amorphous oxide semiconductor and the above-described crystalline oxide semiconductors, a configuration of an oxide semiconductor layer having a layered structure, and the like are described in, for example, JP 2014-007399 A. The entire contents of the disclosure of JP 2014-007399 A are incorporated in the present specification by reference.

The oxide semiconductor layer may include, for example, at least one metal element selected from In, Ga, and Zn. In the present embodiment, the oxide semiconductor layer includes, for example, an In—Ga—Zn—O based semiconductor (for example, an indium gallium zinc oxide). Here, the In—Ga—Zn—O based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. Such an oxide semiconductor layer can be formed of an oxide semiconductor film including the In—Ga—Zn—O based semiconductor.

The In—Ga—Zn—O based semiconductor may be an amorphous semiconductor or may be a crystalline semiconductor. A crystalline In—Ga—Zn—O based semiconductor in which a c-axis is oriented substantially perpendicular to a layer surface is preferable as the crystalline In—Ga—Zn—O based semiconductor.

Note that a crystal structure of the crystalline In—Ga—Zn—O based semiconductor is disclosed, for example, in JP 2014-007399 A described above, JP 2012-134475 A, JP 2014-209727 A, and the like. The entire contents of the disclosures of JP 2012-134475 A and JP 2014-209727 A are incorporated in the present specification by reference. A TFT including an In—Ga—Zn—O based semiconductor layer has a high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In—Ga—Zn—O based semiconductor, the oxide semiconductor layer may include another oxide semiconductor. There may be included, for example, an In—Sn—Zn—O based semiconductor (for example, In₂O₃—SnO₂—ZnO; InSnZnO). The In—Sn—Zn—O based semiconductor is a ternary oxide of In (indium), Sn (tin), and Zn (zinc). Alternatively, the oxide semiconductor layer may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, an In—W—Zn—O based semiconductor, and the like.

### INDUSTRIAL APPLICABILITY

According to the embodiments of the disclosure, in an active matrix substrate including an oxide semiconductor TFT having a top gate structure or a double gate structure as an ESD protection element, it is possible to avoid a problem caused by an excessively high current drive capability of the ESD protection element.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate that includes a display region including a plurality of pixel regions and a non-display region located around the display region, the active matrix substrate comprising:
a substrate;
a plurality of wiring lines provided on the substrate, the plurality of wiring lines including a plurality of gate wiring lines and a plurality of source wiring lines;
a plurality of TFTs supported by the substrate, the plurality of TFTs including a plurality of pixel TFTs disposed in the display region and a plurality of circuit TFTs disposed in the non-display region; and
a plurality of ESD protection elements disposed in the non-display region, each of the plurality of ESD protection elements being electrically connected to a corresponding wiring line of the plurality of wiring lines,
wherein at least some TFTs of the plurality of TFTs include
a first oxide semiconductor layer including a first channel region, and a first source contact region and a first drain contact region located on both sides of the first channel region,
a first gate insulating layer provided at least on the first channel region,
a first gate electrode facing the first channel region via the first gate insulating layer, and
a first source electrode and a first drain electrode electrically connected to the first source contact region and the first drain contact region, respectively, and
each of the plurality of ESD protection elements includes
a second oxide semiconductor layer including a second channel region, and a second source contact region and a second drain contact region located on both sides of the second channel region, the second oxide semiconductor layer being formed in a layer separated from the first oxide semiconductor layer and having a mobility lower than a mobility of the first oxide semiconductor layer,
a second gate insulating layer provided at least on the second channel region,
a second gate electrode facing the second channel region via the second gate insulating layer, and
a second source electrode and a second drain electrode electrically connected to the second source contact region and the second drain contact region, respectively.

2. The active matrix substrate according to claim 1,
wherein the second gate insulating layer includes a first layer and a second layer provided on the first layer, the second layer being formed in a layer identical to the first gate insulating layer.

3. The active matrix substrate according to claim 2, further comprising:
an interlayer insulating layer covering the second oxide semiconductor layer, the second gate insulating layer, and the second gate electrode,
wherein a source contact hole exposing part of the second source contact region and a drain contact hole exposing part of the second drain contact region are formed at least in the interlayer insulating layer, and
the first layer of the second gate insulating layer covers a portion of the second source contact region not overlapping the source contact hole, and a portion of the second drain contact region not overlapping the drain contact hole.

4. The active matrix substrate according to claim 3,
wherein the second layer of the second gate insulating layer covers a portion of the second source contact region not overlapping the source contact hole and a portion of the second drain contact region not overlapping the drain contact hole.

5. The active matrix substrate according to claim 1,
wherein in a plan view, a protrusion width of the second gate insulating layer from the second gate electrode toward the second source contact region side is larger than a protrusion width of the first gate insulating layer from the first gate electrode toward the first source contact region side, and a protrusion width of the second gate insulating layer from the second gate electrode toward the second drain contact region side is larger than a protrusion width of the first gate insulating layer from the first gate electrode toward the first drain contact region side.

6. The active matrix substrate according to claim 1,
wherein the at least some TFTs further include
a third gate electrode located below the first oxide semiconductor layer and facing the at least first channel region, and
a third gate insulating layer located between the first oxide semiconductor layer and the third gate electrode.

7. The active matrix substrate according to claim 6,
wherein the third gate electrode protrudes from the first gate electrode toward the first source contact region side and toward the first drain contact region side in a plan view.

8. The active matrix substrate according to claim 1,
wherein each of the plurality of ESD protection elements further includes
a fourth gate electrode located below the second oxide semiconductor layer and facing the at least second channel region, and
a fourth gate insulating layer located between the second oxide semiconductor layer and the fourth gate electrode.

9. The active matrix substrate according to claim 8,
wherein the fourth gate electrode protrudes from the second gate electrode toward the second source contact region side and toward the second drain contact region side in a plan view.

10. The active matrix substrate according to claim 1,
wherein the second gate electrode and the second source electrode are electrically connected to each other.

11. The active matrix substrate according to claim 1,
wherein the second gate electrode is formed in a layer identical to a layer in which the first gate electrode is formed, and
the second source electrode and the second drain electrode are formed in a layer identical to a layer in which the first source electrode is formed.

12. The active matrix substrate according to claim 1,
wherein at least part of the plurality of pixel TFTs includes a third oxide semiconductor layer formed in a layer identical to the second oxide semiconductor layer.

13. The active matrix substrate according to claim 12,
wherein each of the plurality of pixel TFTs includes the third oxide semiconductor layer.

14. The active matrix substrate according to claim 12,
wherein part of the plurality of pixel TFTs includes the third oxide semiconductor layer, and
another part of the plurality of pixel TFTs includes the first oxide semiconductor layer.

15. The active matrix substrate according to claim 1,
wherein at least part of the plurality of circuit TFTs includes the first oxide semiconductor layer.

16. The active matrix substrate according to claim 1,
wherein the first oxide semiconductor layer and the second oxide semiconductor layer each contain In and/or Sn, and
a sum of atomic ratios of In and Sn to all metal elements in the second oxide semiconductor layer is smaller than a sum of atomic ratios of In and Sn to all metal elements in the first oxide semiconductor layer.

17. The active matrix substrate according to claim 1,
wherein both the first oxide semiconductor layer and the second oxide semiconductor layer contain an In—Ga—Zn—O based semiconductor, and
an atomic ratio of In to all metal elements in the second oxide semiconductor layer is smaller than an atomic ratio of In to all metal elements in the first oxide semiconductor layer.

18. A display device comprising:
the active matrix substrate according to claim 1.

19. The display device according to claim 18,
wherein the display device is a liquid crystal display device.

20. The display device according to claim 18,
wherein the display device is an organic EL display device.
